(19) United States
(12) Patent Application Publication
(10) Pub. No.: US 2024/0395492 A1
(43) Pub. Date: Nov. 28, 2024

(54) COMPENSATION RASTER SCANNING

(71) Applicant: Carl Zeiss SMT GmbH, Oberkochen (DE)

(72) Inventors: Daniel Rhinow, Frankfurt (DE); Soeren Eyhusen, Dieburg (DE)

(21) Appl. No.: 18/674,144

(22) Filed: May 24, 2024

(30) Foreign Application Priority Data
May 26, 2023 (DE) 102023204965.1

(51) Int. Cl. H01J 37/02; H01J 37/28; H01J 37/304

(52) U.S. Cl. CPC H01J 37/026; H01J 37/28; H01J 37/304; H01J 2237/30488; H01J 2237/31794

(57) ABSTRACT

The present disclosure relates to a method for processing and/or examining a sample with a particle beam, comprising: providing the particle beam in a field of view of the particle beam for the purpose of processing and/or examining the sample; providing the particle beam in the field of view for the purpose of setting an electrostatic charge state of the sample. The present disclosure also relates to a corresponding computer program and a corresponding device.

### CROSS-REFERENCE TO RELATED APPLICATION

The present application claims the priority of the German patent application DE 10 2023 204 965.1 with the title “COMPENSATION RASTER SCANNING,” which was filed at the German Patent and Trademark Office on May 26, 2023, the entire content of which is hereby incorporated by reference into this application.

### TECHNICAL FIELD

The present invention relates to a method for processing and/or examining a sample with a particle beam and to a corresponding computer program and a device.

### BACKGROUND

Processing and/or examining a sample with a particle beam is well established. For example, the particle beam may comprise an electron beam, ion beam and/or photon beam which is provided in a defined manner on the sample for the purpose of examining and/or processing the sample. The provision of the particles of the particle beam on the sample allows various interactions to be generated, which can enable various processing processes and/or examinations of the sample. Thus, a particle beam-based processing and/or examination of a sample may comprise very different methods.

For example, the particle beam-based processing may comprise a particle beam-induced etching and/or deposition, within the scope of which material of a sample is removed or generated locally. For example, this may comprise an electron beam-induced etching and/or deposition. Further, a defined photon irradiation of the sample may also be required for the purpose of processing the sample, for example (e.g. in the case of a laser-induced reaction). Examining a sample using a particle beam may for example comprise an image of the sample being recorded with the aid of the particles in the particle beam (e.g. as occurs with the aid of an electron beam in the case of a scanning electron microscope).

A particle beam-based processing and/or examination of a sample with a particle beam is now used in industry for different applications.

For example, in the semiconductor industry, increasingly smaller structures are produced on a wafer in order to ensure an increase in integration density. Among the methods used here for the production of the structures are lithography methods which image these structures onto the wafer. The lithography methods may include, for example, photolithography, ultraviolet (UV) lithography, DUV lithography (i.e. lithography in the deep ultraviolet spectral region), EUV lithography (i.e. lithography in the extreme ultraviolet spectral region), x-ray lithography, nanoimprint lithography, etc. Masks are usually used here as lithography objects (e.g. photomasks, exposure masks, reticles, stamps in the case of nanoimprint lithography, etc.), which comprise a pattern in order to image the desired structures onto a wafer, for example.

As the integration density increases, so do the demands in respect of the mask production (e.g. as a result of the accompanying reduction in the structure dimensions on the mask or as a result of the greater material requirements in lithography). Thus, mask production processes are becoming ever more complex, time consuming and expensive. It is not always possible to avoid mask errors (e.g. defects). Thus, the mask errors are usually repaired by way of particle beam-based processing since they can only be repaired, e.g. in particle beam-based fashion on account of their small dimensions.

Further, it may be necessary to examine samples with a particle beam, for example in the semiconductor industry. For example, the repair of mask errors described herein may require image recordings of the mask errors or the repair location to be made using a particle beam (e.g. for a high-resolution scanning electron microscope image).

Other industrial purposes may also require a processing and/or examination of a sample with a particle beam. For example, this may be carried out for the analysis (e.g. a defect analysis) of a sample which may comprise e.g. a microchip, a wafer, a biological sample, etc.

However, the samples to be processed and/or examined with the particle beam may have an (unwanted) electrostatic charge state.

Unwanted effects may be caused by the (unwanted) electrostatic charge state. For example, the (unwanted) electrostatic charge state may lead to the particle beam being undesirably deflected away from the intended point of incidence on the sample. Further, the electrostatic charge state may also lead to, e.g. a particle beam-based reaction not achieving the desired effect. Thus, the (unwanted) electrostatic charge state may impair the defined processing and/or examination of the sample in an undesired manner.

Thus, a defined processing and/or examination of the sample with a particle beam usually requires a technical workaround for the effects caused by the electrostatic charge state of the sample.

Thus, there is the need for an improvement of the processing and/or examination of samples with a particle beam.

### SUMMARY

This need is at least partly covered by the various aspects described herein.

A first aspect relates to a method for processing and/or examining a sample with a particle beam. The method comprises: providing the particle beam in a field of view of the particle beam to process and/or examine the sample; and providing the particle beam in the field of view to set an electrostatic charge state of the sample.

For example, the first aspect may comprise a method for processing a sample with a particle beam, the method for processing the sample comprising: providing the particle beam in a field of view of the particle beam to process the sample; and providing the particle beam in the field of view to set an electrostatic charge state of the sample.

Thus, the available field of view of the particle beam can be used for two purposes. Firstly, the particle beam may be provided in the field of view for the purpose of examining and/or processing the sample. Secondly, the particle beam may be provided in the same field of view for the purpose of setting an electrostatic charge state of the sample.

Thus, the field of view need not (necessarily) be modified for the purpose of setting the electrostatic charge state of the sample. For example, this can reduce an additional technical outlay that would accompany a modification of the field of view.

For example, one or more parameters of a particle beam device capable of providing the particle beam would typically have to be adapted for a modification of the field of view. For example, a modification of the field of view might sometimes even require a modification of the sample position. In general, a procedure for modifying the field of view may require quite some time, and this is not always desirable from a technical point of view. This is because the usual desire is for a short or minimal processing and/or examination time of the sample with the particle beam. For example, this may be highly relevant especially on an industrial scale, where a comparatively high throughput can be expected for the examination and/or processing of samples with the particle beam. The approach described herein may allow processing and/or examination time periods with the particle beam to be minimized since a modification of the field of view for the purpose of setting the electrostatic charge state is avoided.

For example, the complexity when processing and/or examining the sample can also be reduced by the approach described herein. For example, to set the electrostatic charge state with the particle beam, it is only necessary to address the field of view which is also used for processing and/or examining the sample. For example, the field of view can be configured such that different locations in the field of view can be addressed by the particle beam for the purpose of examining and/or processing the sample. For example, a location in the field of view may correspond to a corresponding location on the sample. This location is addressed by the provision of the particle beam at a location in the field of view, whereby the particles in the particle beam are provided at a corresponding location on the sample. As a result of the approach described herein, setting the electrostatic charge state may also merely require different locations in the field of view (e.g. which was already defined for processing and/or examination purposes) to be addressed by the particle beam. Thus, it is possible to resort to locations already specified by the field of view for the purpose of setting the electrostatic charge state. This can significantly reduce the complexity during the processing and/or examination. Finally, the particle beam is guided into the same field of view for processing and/or examination purposes and for the purpose of setting the electrostatic charge state.

For example, different locations can be determined in the field of view (e.g. by way of a coordinate system and/or by way of pixels) for processing and/or examination purposes. Thus, the particle beam may also simply be provided at one or more of these predetermined locations for the purpose of setting the electrostatic charge state. Hence, there is no need for, e.g. a complex redefinition of the locations to be addressed for the purpose of setting the electrostatic charge state. There is likewise no need to give consideration to a modified field of view for the purpose of setting the electrostatic charge state.

The approach described herein also allows a reliable determination of suitable locations for setting the electrostatic charge state. For example, the locations within the field of view intended to be processed and/or examined may be known. For example, the properties, geometries and/or peculiarities of the sample might also be known at different locations in the field of view (e.g. on the basis of an examination of the sample within the field of view). All of this information regarding the locations of the field of view can also be used for the provision of the particle beam for setting the electrostatic charge state. For example, an image of the sample in the field of view can be used as a basis for finding suitable locations for processing and/or examination purposes and suitable locations for the purpose of setting the electrostatic charge state. If the field of view were modified, then the outlay for the search for suitable locations for the purpose of setting the electrostatic charge state would be increased in this respect. In such a case, locations to be processed and/or examined would have to be defined in a first field of view, with locations for setting an electrostatic charge state then having to be defined in a second of field of view (this being on top of the outlay connected with the field of view modification). This additional outlay can be avoided by the approach described herein.

The method described herein can consequently allow the electrostatic charge state to be set reliably within the scope of processing and/or examining a sample with a particle beam.

For example, it is possible to set the electrostatic charge state of the sample with the particle beam such that this causes an electrostatic charge state which avoids (or minimizes) the unwanted charge effects of the sample when processing and/or examining with the particle beam.

For example, setting the electrostatic charge state of the sample may thus in this respect not comprise setting an arbitrary electrostatic charge state with the particle beam. For example, the provision of the electrostatic charge state of the sample may not comprise the creation of a parasitic charge state in the sample which adversely affects the processing and/or examination of the sample with the particle beam. Instead, the intention is to cause an electrostatic charge state that optimizes processing and/or examining with the particle beam.

Thus, setting the electrostatic charge state may be considered as, e.g. implementing a targeted setting of the electrostatic charge state in view of processing and/or examining, in order to influence this purposefully from a technological point of view. Thus, the setting may be such that unwanted charges and/or charge effects can be minimized during the processing and/or examination. Thus, setting the electrostatic charge state cannot be considered to be simply any manner of particle beam bombardment of the sample, within the scope of which an arbitrary charge state (possibly unknown in terms of sign and absolute value) is generated and may cause negative effects on the processing and/or examination of the sample. For example, unwanted charge states and charge effects may arise, especially when providing the particle beam for processing and/or examining the sample. This can be addressed purposefully by setting the electrostatic charge state. Thus, this allows an unwanted charge in the sample to be compensated for by the setting process. Further, it is also possible to maintain a charge of the sample (as described herein), with the result that the unwanted charge effects are minimized over a period of time, and so processing and/or examination is/are optimized (and e.g. fewer bothersome charge effects occur) during this period of time.

By contrast, known approaches e.g. accept the unwanted charge effects that might undesirably deflect the particle beam. Thus, the particle beam is not really incident at the set target position on the sample on account of the unwanted charge effects. Thus, known approaches initially see the determination of the unwanted charge effects, for example on the basis of drift markers located on the sample. Subsequently, the particle beam is steered onto the sample with an offset based on this information, with the result that said particle beam lands at the actual target position on the sample despite the unwanted charge effects. This approach is known under the keyword drift correction. However, this approach is not always suitable for all applications.

By contrast, the method described herein can directly influence the actual cause for the unwanted particle beam deflection, specifically the charge state of the sample. Thus, the electrostatic charge state is actively set or compensated by way of the provision of the particle beam in the field of view (and not simply accepted as a matter of course).

It should be mentioned that the provision of the particle beam for examination and/or processing purposes and the provision of the particle beam for the purpose of setting the electrostatic charge state need not (necessarily) be restricted to a certain sequence.

In an example, the particle beam for setting the electrostatic charge state can be provided before the particle beam for processing and/or examination purposes is provided in the field of view. Consequently, unwanted charge effects of the sample can be minimized during the processing and/or examination.

For example, the method may comprise: providing the particle beam in a field of view of the particle beam for the purpose of processing the sample (which might cause, e.g. an electrostatic charge state of the sample), with this being followed by a provision of the particle beam in the field of view for the purpose of setting the electrostatic charge state of the sample.

However, the method can also comprise the provision of the particle beam for processing and/or examination purposes to be followed by a provision of the particle beam for the purpose of setting the electrostatic charge state Subsequently, there can be e.g. a renewed provision of the particle beam for processing and/or examination purposes.

Thus, the steps of the method described herein may also occur iteratively. For example, the method may comprise, e.g. two or more processing steps, in each of which the particle beam on the sample is provided in the same field of view. The particle beam for setting the electrostatic charge state of the sample can be provided in the field of view between the processing steps. For example, an unwanted electrostatic charge state may have been caused by a processing step with the particle beam, with the result that the processing no longer proceeds as desired. Therefore, the particle beam can be used to set the electrostatic charge state such that the subsequent processing step can initially occur as desired (e.g. without bothersome charge effects). If this processing step should once again lead to an unwanted electrostatic charge state of the sample, then the electrostatic charge state can be set again. This procedure can be repeated as often as desired.

The example set forth below is also mentioned in this respect. For example, the method may include an initial provision of the particle beam in the field of view for processing purposes and this may be followed by the provision of the particle beam in the field of view for the purpose of setting the electrostatic charge state, with this possibly being followed by a renewed provision of the particle beam in the field of view for processing purposes.

According to the approach described herein, the step of providing the particle beam for processing (and/or examination) purposes in the field of view and the step of providing the particle beam for the purpose of setting the electrostatic charge state in the field of view of the sample can therefore be repeated and/or combined in any desired order.

In respect of the approach described herein, the example set forth below can also be mentioned. For example, the method may comprise: providing the particle beam at a first location in the field of view of the particle beam for the purpose of processing and/or examining the sample; providing the particle beam at a second location in the field of view for the purpose of setting an electrostatic charge state of the sample. It is mentioned in this context that the terms first location and second location can be considered a categorization in respect of the (functional) step carried out with the particle beam. Thus, as a matter of principle, a first location may comprise a location at which the particle beam is provided for the purpose of processing and/or examining the sample. As a matter of principle, the second location may comprise a location at which the particle beam is provided for the purpose of setting the electrostatic charge state. For example, over the course of a method, different locations in the field of view may be addressed by the particle beam for processing and/or examination purposes. If a location is addressed for processing and/or examination purposes, then this location can fall under the category of first location. Likewise, over the course of the method, different locations in the field of view can be addressed by the particle beam for the purpose of setting the electrostatic charge state. If a location is addressed for the purpose of setting an electrostatic charge state, then this location can fall under the category of second location. It should be noted that the categorization provides for the first and second locations to not necessarily differ from one another (as described herein). To present the approach described herein, the explanations hereinafter occasionally resort to the categorization according to first location and second location.

In an example, the field of view may comprise a region that is able to be addressed by the particle beam. Accordingly, the field of view may comprise a region of the sample which can be addressed by the particle beam (e.g. without moving a sample holder and/or other parts of the device used for the method).

For example, the field of view may comprise a region of the sample to be processed and/or imaged, which can be addressed by the particle beam.

In an example, the field of view may comprise a region to be processed and/or imaged and a further region of the sample, wherein the further region may adjoin the region to be processed and/or imaged. In this example, the particle beam can address both the region to be processed and/or imaged and the further region. In this example, the region to be processed and/or imaged represents a subset of the field of view. In this example, the particle beam need not necessarily be provided in the further region, although this would be possible since the further region also represents a subset of the field of view.

In an example, the field of view can be considered to be a region in the angle of view of a particle beam device that provides the particle beam, with the particle beam action of the particle beam being restricted to this region. In this respect, the field of view can also be abbreviated FOV. For example, the field of view can be defined by virtue of the particle beam being able to be moved over the field of view on the sample due to the application of different electric and/or magnetic fields that serve to deflect the particle beam, without however the particle beam source or the sample being moved.

For example, the field of view can also, e.g. be considered to be a scanning field comprising a plurality of scan points. All scan points in the field of view can be accessible to the particle beam by way of a deflection of the particle beam vis-à-vis a deflection point. For example, the deflection point may comprise an aperture and/or a focus of the particle beam device. With regard to the deflection point, the particle beam can emerge in a defined way at various angles. However, the possible angles at which the particle beam can emerge from the deflection point may be limited. This can give rise to a scanning field accessible to the particle beam (e.g. at a certain distance from the deflection point, for example in a sample plane). This scanning field accessible to the particle beam can be considered to be the field of view described herein. In other words, the field of view can be considered in this way, e.g. as a natural boundary within which the particle beam can address any desired points (on the sample) by way of a deflection or change in angle. For example, the particle beam cannot address any points of the sample beyond the field of view.

One aspect with regard to limiting the particle beam action can be that the beam parameters (e.g. an aperture and/or a focus) are designed such that there is a need for only limited change thereof over the course of sweeping over the restricted region.

Setting the electrostatic charge state of the sample with the particle beam shall also be explained. In principle, to set the electrostatic charge state, the sample may be electrostatically charged positively, negatively or neutrally by the provision of the particle beam in the field of view of the sample. In this case, it may be sufficient to appropriately adapt the particle beam in order to set the (desired) electrostatic charge state. For example, the basic mechanism for setting the electrostatic charge state can be understood as creating two charge flows that are capable of influencing the net charge of the electrostatic charge state of the sample. Firstly, the particle beam provided for setting the electrostatic charge state optionally introduces a charge into the sample (as first charge flow). Secondly, however, this may cause a reaction in the sample, within the scope of which charge may be removed from the sample (as second charge flow). Consequently, this can create a resultant net charge of the sample in a targeted manner. For example, a defined net charge with a positive or negative sign can be created as resultant net charge.

Through this mechanism, setting the electrostatic charge state may for example comprise the generation of a (pre-)defined net charge in the sample. Thus, the sample can be purposefully set to a desired (e.g. quantifiable) value. For example, the (pre-)defined net charge can be a net charge fixed in terms of sign and absolute value. The (pre-)defined net charge can thus be quantified as +Q or −Q for example, where Q specifies a charge value. The set (pre-)defined net charge can be verified or adapted to the desired value by virtue of determining the charge state of the sample.

For example, a particle beam whose energy is high enough to release electrons from the sample may cause electrostatic charging of a sample, in particular of an electrically non-conductive sample or of an electrically conductive non-grounded sample.

Should the particle beam incident on the sample, which particle beam is also referred to below as primary beam, contain electrically neutral particles, such as photons and/or atoms, an electrically insulating sample can be, e.g. positively electrostatically charged. Since the primary beam is not supposed to have a destructive effect on the sample during processing and/or examination of the sample, i.e. a sputtering effect is undesirable, the photons and/or atoms of the primary beam primarily generate free electrons in the sample. Some of these electrons may leave the sample as secondary particles. In addition to photons of various wavelengths, secondary particles in particular include secondary electrons (SE) and/or backscattered particles (BSE standing for backscattered electrons; if the primary beam contains electrons) that are used to detect an electrostatic sample charge state. The SE and BSE leaving the sample result in a positive excess charge of the sample irradiated by the primary beam. Depending on the introduction of charge by the primary beam, the net charge (i.e. the excess charge) of the sample can be positive, negative or neutral.

A primary beam comprising electrically neutral or positively charged particles generates SE, but not BSE. Typically, BSE are generated only when the primary beam comprises electrons. This should be taken into consideration when the release of SE and BSE by a particle beam is mentioned below.

The charge balance when a sample is irradiated with a primary beam containing positively charged ions is likewise positive. As a result of the ions in the primary beam, the latter introduces positive charges into the sample, and the SE additionally remove negative charges from the sample, as a result of which said sample is positively electrostatically charged. The positive excess charge may be set for example by irradiation with electrons having an appropriately adjusted landing energy.

If negatively charged particles, e.g. electrons, are used in the primary beam, the charge balance of the sample may turn out to be positive, negative or neutral, depending on whether on average more or less than one secondary particle (sum of BSE and SE) is able to leave the sample per negatively charged particle, incident on the sample, of the primary beam.

The charge balance of the sample when irradiated with particle beams that have a mass may depend on the landing energy of the particles on the sample. For example, at a very low landing energy, the particles that have a mass of the primary beam may release on average less than one secondary particle (BSE and SE) per incident primary particle, e.g. possibly resulting in a low electrostatic charge state of the sample, the sign of which is determined by the charge of the particles of the primary beam. As landing energy increases, the number of SE and BSE able to leave the sample may increase, as therefore also does the electrostatic charge state thereof. As described above, the sign of the electrostatic sample charge state may be reversed depending on the charge of the particles of the primary beam.

In the case of electrons, e.g. used as primary beams, the charge balance can be negative for low landing energies, and so a sample can be negatively electrostatically charged. In a medium landing energy range, an electron of the primary beam can generate on average a total of more than one SE and BSE, whereby the sample can be positively electrostatically charged. At high landing energies of the electrons of the primary beam, the generation rate of SE and BSE may decrease again, and the penetration depth of the primary electrons may increase at the same time, with the result that the electric charge introduced into the sample by the electrons of the primary beam can dominate the charge balance.

If e.g. photons are used as primary beams, there is a threshold for their wavelength starting from which the light quanta are able to release electrons from their bonds in the sample. As wavelength decreases, i.e. as energy increases, their electron release rate, i.e. their SE generation rate or their yield coefficient, increases. If photons have a wavelength that is shorter than the limit wavelength, the SE generation rate additionally depends on the flux density at which the primary beam is incident on the sample. This means that, the greater the beam strength of a photon beam (above the energy threshold), the larger the SE beam generated by the sample.

In an example, the electrostatic charge state may be set purely by way of the particle beam provided. For example, in this way it may be possible to eliminate the need for an additional means for setting the electrostatic charge state of the sample. However, it is also conceivable that a further means for setting the electrostatic charge state is additionally used to complement the electrostatic charge state being set by way of the particle beam.

In an example, the method may further comprise: providing a gas for removing and/or depositing a material in the field of view, at least in part on the basis of the particle beam provided in the field of view for processing and/or examination purposes. For example, the gas may be provided at the first location (described herein) for removing and/or creating a material in the field of view based at least in part on the particle beam provided at the first location.

Thus, sample material can be removed and/or deposited using the particle beam provided for processing and/or examination purposes and the gas provided. In this context, removal and/or deposition with the aid of the gas can also be considered to be processing of the sample. For example, this may comprise a particle beam-induced etching and/or deposition using the gas provided. For example, the gas can be provided locally in the region in which the particle beam is provided for the purpose of processing the sample. For example, the particle beam-induced etching may comprise an electron beam-induced etching. For example, the particle beam-induced deposition may comprise an electron beam-induced deposition.

In an example, the gas may comprise one or more components (e.g. a main gas for etching or deposition purposes and additional additive gases).

In an example, the provision of the gas may be interrupted when the particle beam is provided for the purpose of setting the electrostatic charge state. For example, the gas might not be provided when the electrostatic charge state is set. For example, this can allow the gas to diffuse away from the sample. For example, this can ensure that the concentration of the gas present at the sample is lower than when the gas is provided. As a result, the gas might be present at a comparatively lower concentration, including at the location at which the particle beam is provided for electrostatic charging. For example, this can avoid a particle beam-induced reaction with the gas when the electrostatic charge state is set.

In an example, a predetermined waiting time may be observed between the provision of the gas and the provision of the particle beam for the purpose of setting the electrostatic charge state. For example, this may ensure that enough time has elapsed for the gas to diffuse so that a particle beam-induced reaction can be prevented (or at least limited) when the electrostatic charge state is set.

In an example, it is also conceivable to actively evacuate the gas before the electrostatic charge state is set.

However, in an example, it is also conceivable that the gas for removing and/or depositing the material could be provided at the same time as the particle beam for setting the electrostatic charge state. For example, when the particle beam for setting the electrostatic charge state is provided, one or more particle beam parameters can be present that are able to prevent (or at least limit) a particle beam-induced reaction with the gas. In an example, the removal and/or deposition of material may also be tolerated when the particle beam is provided for the purpose of setting the electrostatic charge state.

In an example, the particle beam in the field of view for processing and/or examination purposes may be provided in a predetermined active region which can make up a subset of the field of view. For example, the first location (described herein) may be located in a predetermined work and/or examination region.

For example, the predetermined active region may contain a pixel grid, whereby a localization of one or more locations of the sample can be rendered possible. In this case, the pixel grid may make up a subset of the accessible field of view. Within the pixel grid, the sample can be processed and/or examined with the particle beam provided. For example, as a processing step, particle beam-induced etching and/or a particle beam-induced deposition can be implemented within the pixel grid using the particle beam provided. For example, the particle beam can be used for examination purposes (e.g., record an image of the predetermined active region) within the pixel grid. In an example, processing may be implemented within the predetermined active region, while the examination is implemented within the entire field of view. For example, it may be necessary to examine the sample with the particle beam both within and outside of the predetermined active region, whereas the processing should be restricted, e.g. to the predetermined active region (e.g. the pixel grid).

In an example, processing and/or examining the sample with the particle beam may comprise processing and/or examining a defect in the sample with the particle beam. In this respect, the predetermined active region can be designed for processing and/or examining the defect. The predetermined active region or the corresponding pixel grid may also be referred to as, e.g. a repair shape.

For processing and/or examining the defect, the corresponding pixel grid (as exemplary predetermined active region) may, for example, be designed such that it follows the outline of the defect, such that every pixel in the pixel grid corresponds essentially to a location in the defect and hence constitutes a defect pixel. In another example, the pixel grid has a fixed geometric shape (e.g. a polygon, a rectangle, a circle, etc.) which fully encompasses the defect, in which case not every pixel necessarily constitutes a defect location. It is possible here for the pixel grid to include defect pixels corresponding to a defect location, and non-defect pixels corresponding to a location which does not cover part of the defect. In an example, the method comprises directing the particle beam at least to a defect pixel of the pixel grid during the processing and/or examination. Further, the particle beam may be configured such that it can be directed to any defect pixel during the processing and/or examination. This can ensure that the processing and/or examination is locally restricted to the defect pixels and hence only the defect is processed or examined.

In an example, the particle beam can be provided in the predetermined active region in the field of view for the purpose of setting the electrostatic charge state of the sample. For example, in this respect, the second location (described herein) may also be located in the predetermined work and/or examination region which makes up a subset of the field of view.

For example, the particle beam can be provided in the predetermined active region for processing and/or examination purposes, with the particle beam likewise being provided for the purpose of setting the electrostatic charge state in the predetermined active region. Thus, for example, one or more pixels of the pixel grid (as exemplary predetermined active region) can be addressed by the particle beam for the purpose of processing and/or examining the sample, wherein one or more pixels of the pixel grid can also be addressed for the purpose of setting the electrostatic charge state.

This approach allows the electrostatic charge state to be set directly in the active region. This makes it possible to ensure that the set electrostatic charge state is essentially local there. Accordingly, this local electrostatic charge state may bring about a local electric field. The latter can influence the particle beam provided in the active region for processing and/or examination purposes. Thus, unwanted effects of the electrostatic charge state of the sample can be reduced more efficiently in the region in which the processing and/or examination is implemented as well.

For example, it is not always possible to make the assumption that setting the electrostatic charge state at any desired location on the sample also has an effect on the particle beam during the processing and/or examination. For example, the charge induced by the setting need not always be distributed uniformly over the sample. Instead, there may be local variations which may depend, e.g. on the local conductivity of the sample. For example, insulating structures of the sample may prevent the set electrostatic charge state transitioning to the processing and/or examination location. Thus, setting the electrostatic charge state at an arbitrary location cannot always ensure that the charge induced by the setting has an (e.g. corrective) effect on the particle beam during the processing and/or examination.

However, if the particle beam for setting the electrostatic charge state is provided in the same active region in which the particle beam is also used for processing and/or examination purposes, then it is possible to more reliably ensure that the induced set charge can also have an (e.g. corrective) effect on the particle beam.

In an example, the particle beam can be provided at the same location in the field of view for processing and/or examination purposes and for the purpose of setting the electrostatic charge state. For example, in the field of view, the first location (described herein) may also correspond to the second location (described herein). It should be observed that this example need not (necessarily) be restricted to the predetermined active region. Rather, this concept may also be applied independently of the active region. As a matter of principle, this approach encompasses the case that (within the scope of the method) a location in the field of view which can be addressed by the particle beam for processing and/or examination purposes can also be addressed by the particle beam for the purpose of setting the electrostatic charge state.

Consequently, it is possible to ensure that the electrostatic charge state is induced at the location at which the particle beam is also used for processing and/or examination purposes. For example, this can allow the induced electrostatic charge state to be present directly at the location at which the particle beam is directed for processing and/or examination purposes. Consequently, the electric field caused by the electrostatic charge state can likewise be present directly at the location at which the particle beam is directed for processing and/or examination purposes. This approach makes it possible to prevent or more efficiently reduce interfering mechanisms such as an inadequate charge transfer to the processing and/or examination location. This can therefore allow the (e.g. corrective) effect of the set electrostatic charge state to act reliably on the particle beam during processing and/or an examination.

For example, this approach of allowing the same location to be addressed by the particle beam for processing and/or examination purposes and for the purpose of setting the electrostatic charge state can be implemented within the active region. As described, the active region may, e.g. contain a pixel grid (or be defined by way of a pixel grid). An appropriate example is given in this respect. The particle beam for processing and/or examination purposes can be provided on a first pixel of the pixel grid. The particle beam for setting the electrostatic charge state can also be provided on this first pixel of the pixel grid. Thus, an electrostatic charge state can be induced, e.g. in pixel-specific fashion.

In an example, it is not necessary for every pixel to be processed and/or examined to also be addressed by the particle beam for the purpose of setting the electrostatic charge state. For example, it may be sufficient if a subset of pixels in the pixel grid which are processed and/or examined with the particle beam are addressed by the particle beam for the purpose of setting the electrostatic charge state. For example, the electrostatic charge state set at a pixel with the particle beam may also have an (e.g. corrective) effect on surrounding pixels. For example, if these surrounding pixels are processed and/or examined with the particle beam, it may not always be necessary to set their electrostatic charge state.

However, it is also conceivable in an example that all pixels in the pixel grid which are addressed by the particle beam for processing and/or examination purposes are also addressed by the particle beam for the purpose of setting the electrostatic charge state.

In an example, the particle beam can be provided at different locations in the field of view for processing and/or examination purposes and for the purpose of setting the electrostatic charge state. For example, in this regard, the first location (described herein) may differ from the second location (described herein). It should be observed that this example need not (necessarily) be restricted to the predetermined active region. Rather, this concept may also be applied independently of the active region. As a matter of principle, this approach encompasses the case that (within the scope of the method) a location in the field of view which is addressed by the particle beam for processing and/or examination purposes may differ from a location which can be addressed by the particle beam for the purpose of setting the electrostatic charge state.

For example, an electrically conductive connection may be present between the location at which the electrostatic charge state is set and the location at which the processing and/or examination is implemented. Thus, the charge induced at the location where the electrostatic charge state is set (the second location) may also significantly influence the location at which the processing and/or examination is implemented (the first location). Thus, it is not always necessary for a location to be processed and/or examined in the field of view to also be addressed for the purpose of setting the electrostatic charge state. For example, it might be conceivable to have dedicated locations in the field of view, with these being addressed (e.g. exclusively) by the particle beam for the purpose of setting the electrostatic charge state. These dedicated locations need not necessarily be addressed by the particle beam for, e.g. processing and/or examination purposes.

For example, this approach of allowing a location for processing and/or examination purposes to differ from a location addressed by the particle beam for the purpose of setting the electrostatic charge state can be implemented within the active region. As described, the active region may, e.g. contain a pixel grid (or be defined by way of a pixel grid). An appropriate example is given in this respect. The particle beam for processing and/or examination purposes can be provided on a first pixel of the pixel grid. The particle beam for setting the electrostatic charge state may be provided at a second pixel of the pixel grid, which differs from the first pixel.

It is mentioned in an example that the provision of the particle beam in the field of view for processing and/or examination purposes may be implemented in the predetermined active region which makes up a subset of the field of view, wherein the provision of the particle beam in the field of view for the purpose of setting the electrostatic charge state of the sample may be implemented outside of the predetermined active region. For example, the first location may be located in the predetermined active region, with the second location being located outside of the predetermined active region. As described, the active region may, e.g. contain a pixel grid (or be defined by way of a pixel grid). For example, the particle beam can be directed at a pixel in this pixel grid for examination and/or processing purposes. For the purpose of setting the electrostatic charge state, the particle beam may be provided outside of this pixel grid in the field of view.

Further examples arising from the approach described herein are also mentioned.

In an example, it is conceivable that (within the scope of the method) the particle beam addresses a first set of locations in the field of view for processing and/or examination purposes and for the purpose of setting the electrostatic charge state, while the particle beam addresses a second set of locations in the field of view, different from the first, purely for processing and/or examination purposes.

In an example, it is conceivable that (within the scope of the method) the particle beam addresses a first set of locations in the field of view for processing and/or examination purposes and for the purpose of setting the electrostatic charge state, the particle beam addresses a second set of locations in the field of view purely for processing and/or examination purposes and the particle beam addresses a third set of locations in the field of view purely for the purpose of setting the electrostatic charge state. In this case, the first, second and third sets of locations may differ from one another.

In an example, it is also conceivable that (within the scope of the method) the particle beam addresses a first set of locations in the field of view purely for processing and/or examination purposes and the particle beam addresses a second set of locations in the field of view, different from the first, purely for the purpose of setting the electrostatic charge state.

In an example, a location in the field of view at which the particle beam is provided for processing and/or examination purposes and a location in the field of view at which the particle beam is provided for the purpose of setting the electrostatic charge state are spaced apart by at most 20 μm, e.g. at most 10 μm, preferably at most 5 μm, more preferably at most 4 μm, even more preferably at most 3 μm and most preferably at most 2 μm, 1 μm or 500 nm. For example, in this respect, the second location (described herein) and the first location (described herein) are spaced apart by at most 20 μm, e.g at most 10 μm, preferably at most 5 μm, more preferably at most 4 μm, even more preferably at most 3 μm and most preferably at most 2 μm, 1 μm or 500 nm.

Thus, a repair of a local defect can, e.g. be implemented with the aid of the particle beam (and a corresponding precursor gas and optionally additional gases), wherein the particle beam for charge compensation is used at a location spaced apart from the defect by at most 20 μm, e.g. at most 10 μm, preferably at most 5 μm, more preferably at most 4 μm, even more preferably at most 3 μm and most preferably at most 2 μm, 1 μm or 500 nm.

It is emphasized that the distances specified in the two preceding paragraphs may be significant, also independently of a field of view. Thus, in an example, a location at which the particle beam is provided for processing and/or examination purposes and a location at which the particle beam is provided for the purpose of setting the electrostatic charge state are spaced apart by at most 20 μm, e.g. at most 10 μm, preferably at most 5 μm, more preferably at most 4 μm, even more preferably at most 3 μm and most preferably at most 2 μm, 1 μm or 500 nm. For example, in this respect, the second location (described herein) and the first location (described herein) are spaced apart by at most 20 μm, e.g. at most 10 μm, preferably at most 5 μm, more preferably at most 4 μm, even more preferably at most 3 μm and most preferably at most 2 μm, 1 μm or 500 nm. Similarly, a repair of a local defect can, e.g. be implemented with the aid of the particle beam (and a corresponding precursor gas and optionally additional gases), wherein the particle beam for charge compensation is used at a location spaced apart from the defect by at most 20 μm, e.g. at most 10 μm, preferably at most 5 μm, more preferably at most 4 μm, even more preferably at most 3 μm and most preferably at most 2 μm, 1 μm or 500 nm.

In an example, at least one particle beam parameter may differ between the provision of the particle beam in the field of view for processing and/or examination purposes and the provision of the particle beam in the field of view for the purpose of setting the electrostatic charge state. For example, in this regard, the provision of the particle beam at the second location (described herein) may be implemented with at least one different particle beam parameter than the provision of the particle beam at the first location (described herein).

For example, it is conceivable that setting the electrostatic charge state requires different particle beam parameters to the processing and/or examination of the sample. Thus, the provision of the particle beam for the purpose of processing and/or examining the sample may differ from the provision of the particle beam for the purpose of setting the electrostatic charge state.

In an example, the at least one different particle beam parameter may comprise at least one of the following parameters: a landing energy of the particles in the particle beam incident on the sample, a wavelength of the particles in the particle beam incident on the sample, a flux density of the particles in the particle beam incident on the sample, an irradiation time of the particles in the particle beam incident on the sample, a particle beam current of the particles in the particle beam incident on the sample, and an acceleration of the particles in the particle beam incident on the sample. For example, the acceleration can be set by way of an acceleration voltage for a particle beam source which provides the particle beam. Accordingly, the at least one different particle beam parameter may also comprise an acceleration voltage of the particles incident on the sample.

For example, the particle beam for processing and/or examining the sample may be provided with a first landing energy, while the particle beam for setting the electrostatic charge state is provided with a different second landing energy. For example, the particle beam for processing and/or examining the sample may be provided at a first wavelength, while the particle beam for setting the electrostatic charge state is provided at a different second wavelength. For example, the particle beam for processing and/or examining the sample may be provided with a first flux density, while the particle beam for setting the electrostatic charge state is provided with a different second flux density. For example, the particle beam for processing and/or examining the sample may be provided with a first irradiation time, while the particle beam for setting the electrostatic charge state is provided with a different second irradiation time. For example, the particle beam for processing and/or examining the sample may be provided with a first particle beam current, while the particle beam for setting the electrostatic charge state is provided with a different second particle beam current. For example, the particle beam for processing and/or examining the sample may be provided with a first acceleration of the particles in the particle beam current, while the particle beam for setting the electrostatic charge state is provided with a different second acceleration of the particles in the particle beam current. For example, the particle beam for processing and/or examining the sample may be provided with a first acceleration voltage of the particles in the particle beam current, while the particle beam for setting the electrostatic charge state is provided with a different second acceleration voltage of the particles in the particle beam current.

The flux density, the irradiation area and the irradiation time of the particles in the particle beam incident on the sample may determine the irradiation dose applied by the particle beam. The irradiation dose may be applied to a location of the sample through a single irradiation operation for a period of time that is determined by the irradiation dose. The irradiation dose may also be applied in partial doses through periodic irradiation. The particle beam, in order to apply a predefined irradiation dose in a region of a sample, may be raster-scanned or scanned over same. The beam spot of the particle beam may be adapted to that region of the sample to be irradiated.

For example, the particle beam for processing and/or examining the sample may be provided with a first irradiation dose, while the particle beam for setting the electrostatic charge state is provided with a different second irradiation dose.

In an example, the at least one different particle beam parameter may comprise an area dose in relation to a portion of the field of view, with the area dose being introduced in the portion by the particle beam. For example, the particle beam for processing and/or examining the sample may be provided with a first area dose in a given portion, while the particle beam for setting the electrostatic charge state is provided with a different second area dose in the given portion.

As described herein, the particle beam may be provided on one or more pixels in the field of view (e.g. on the pixels in the predetermined active region). In this respect, the at least one different particle beam parameter may comprise a (particle beam) dose per pixel. For example, in relation to a pixel, the particle beam for processing and/or examining the sample may be provided with a first dose, while the particle beam for setting the electrostatic charge state is provided with a different second dose acting on this pixel.

For example, the at least one different particle beam parameter may also comprise a dwell time of the particle beam on a pixel. For example, in relation to a pixel, the particle beam for processing and/or examining the sample may be provided with a first dwell time on this pixel, while the particle beam for setting the electrostatic charge state is provided on this pixel with a different second dwell time. Thus, the particle beam can be directed at a pixel for a first time for processing and/or examination purposes, while the particle beam is directed at this pixel for a different second time for the purpose of setting the electrostatic charge state.

In an example, the sample might not be displaced between the provision of the particle beam in the field of view for processing and/or examination purposes and the provision of the particle beam in the field of view for the purpose of setting the electrostatic charge state. Thus, for example, the sample might not be displaced between the provision of the particle beam at the first and second location.

Using the approach described herein, it is thus possible to make do without a modification of the sample position. Rather, addressing locations in the field of view for processing and/or examination or field of view for setting the electrostatic charge state is sufficient for the method. As mentioned, this not only allows time to be saved but also reduces the complexity of the method.

In an example, the particle beam source of the particle beam might not be displaced between the provision of the particle beam in the field of view for processing and/or examination purposes and the provision of the particle beam in the field of view for the purpose of setting the electrostatic charge state. Thus, for example, the particle beam source of the particle beam might not be displaced between the provision of the particle beam at the first and second location.

Using the approach described herein, it is thus possible to make do without a modification of the position of the particle beam source (and/or the sample). Rather, addressing locations in the field of view for processing and/or examination or field of view for setting the electrostatic charge state is sufficient for the method. As mentioned, this not only allows time to be saved but also reduces the complexity of the method.

In an example (as mentioned herein), the particle beam can be provided in the field of view for the purpose of setting the electrostatic charge state before the particle beam is provided in the field of view for processing purposes. For example, setting the electrostatic charge state may be based on a determination of one or more parameter values described below.

In an example, the method may further comprise: determining an electrostatic charge state of the sample. For example, the electrostatic charge state of the sample can be determined on the basis of reference structures analyzed with the particle beam. For example, the electrostatic charge state can be determined on the basis of one or more drift markers which might be situated on the sample for drift correction purposes (as described herein). On the basis of a reference position of the one or more drift markers, an electrostatic charge state of the sample can be determined using the current position of the one or more drift markers, for example. Further, other ways for determining an electrostatic charge state of the sample are also conceivable without restrictions (e.g. also by measuring the charge state).

In an example, the electrostatic charge state can be determined before the provision of the particle beam in the field of view for the purpose of setting the electrostatic charge state, with the provision of the particle beam in the field of view for the purpose of setting the electrostatic charge state being based at least in part on the determined electrostatic charge state.

Thus, the electrostatic charge state can be set on the basis of the previously determined electrostatic charge state of the sample. For example, it is possible to set a defined portion of an electrostatic charge state which depends on the previously determined electrostatic charge state of the sample.

For example, the electrostatic charge state can be set such that the sample essentially has a net charge of zero (or a net charge of zero at the location addressed by the particle beam for processing and/or examination purposes). Thus, setting the electrostatic charge state can put the sample (or the location addressed by the particle beam for processing and/or examination purposes) into an electrically neutral state. The previously existing electric charge state of the sample can therefore be compensated for by the method described herein.

For example, an electrostatic charge state portion of the sample of −C1 may have been determined. Thus, an electrostatic charge state portion of +C1 would be required for compensation purposes. Thus, this portion of +C1 can be introduced into the sample for compensation purposes by way of the provision of the particle beam for setting the electrostatic charge state.

For example, the electrostatic charge state can be set such that the sample essentially has a positive excess charge (or a positive excess charge at the location addressed by the particle beam for processing and/or examination purposes). Thus, setting the electrostatic charge state can put the sample (or the location addressed by the particle beam for processing and/or examination purposes) into an electrically positive state. For example, this may be advantageous in order to maintain a certain electrostatic charge state of the sample. For example, negative charge might be introduced into the sample over time during the processing and/or examination. Thus, the negative charge in the sample might increase over time. The particle beam might be impaired severely during the processing and/or examination after a certain time at which a critical negative charge state is reached, and may result in the processing and/or examination by the particle beam to be severely impaired. This time can be delayed as a result of maintaining the positive excess charge. In this case, the positive excess charge must initially be neutralized by the introduced negative charge within the scope of processing and/or examination. Post-neutralization, the negative charge introduced by processing and/or examination causes a negative excess charge, and so the critical negative charge state can ultimately be reached. However, maintaining the positive excess charge delays the critical charge state being reached.

For example, a certain electrostatic charge state portion of the sample may have been determined. Subsequently, it is possible to determine a portion of the electrostatic charge state that needs to be introduced in order for example to set the sample to a positive excess charge of +C2. The provision of the particle beam for the purpose of setting the electrostatic charge state can be adapted accordingly in order to introduce this positive excess charge into the sample.

Analogously, for example, the electrostatic charge state can be set such that the sample essentially has a negative excess charge (or a negative excess charge at the location addressed by the particle beam for processing and/or examination purposes). For example, positive charge might be introduced into the sample over time during the processing and/or examination. Accordingly, it is then possible to maintain a negative charge state, for example.

For example, a certain electrostatic charge state portion of the sample may have been determined Subsequently, it is possible to determine a portion of the electrostatic charge state that needs to be introduced in order for example to set the sample to a negative excess charge of −C3. The provision of the particle beam for the purpose of setting the electrostatic charge state can be adapted accordingly in order to introduce this negative excess charge into the sample.

In an example, in order to verify the electrostatic charge state set by the particle beam provided, the electrostatic charge state can be determined after the particle beam has been provided in the field of view for the purpose of setting the electrostatic charge state.

Thus, the portion of the electrostatic charge state can be verified again following the latter being set. Subsequently, the electrostatic charge state can be, e.g. readjusted with the particle beam.

In an example (as mentioned herein), there can be an initial provision of the particle beam in the field of view for processing purposes and this may be followed by the provision of the particle beam in the field of view for the purpose of setting the electrostatic charge state, with this possibly being followed by a renewed provision of the particle beam in the field of view for processing purposes. For example, the electrostatic charge state might be determined between the initial provision of the particle beam for processing purposes and the subsequent provision of the particle beam for the purpose of setting the electrostatic charge state. After the electrostatic charge state has been set, there can be, e.g. a renewed determination of the electrostatic charge state for verification purposes. If the latter has the desired value, there can be another processing step with the particle beam.

In an example, the sample may comprise a lithography object.

The lithography object may comprise, e.g. a mask for a lithographic method. For example, the lithography object may comprise an optical lithography object (e.g. the object might be designed to be exposed to an exposure radiation during the optical lithography). For example, the object may comprise an EUV mask for EUV lithography. However, it is also conceivable that the object comprises a mask for any other optical lithographic method, e.g. for DUV lithography, UV lithography and/or x-ray lithography. For example, the object may comprise a transmissive and/or reflective mask for (optical) lithography. Thus, e.g. the mask may be designed such that the exposure radiation is transmitted by the mask or reflected by the mask during (optical) lithography. It is also conceivable that the lithography object need not necessarily comprise an optical lithography object. For example, the lithography object might also be designed for non-optical lithography, e.g might also comprise a stamp for nanoimprint lithography.

In an example, the lithography object may also comprise a mask blank. In the lithographic industry, mask blanks are a known starting material for a mask. For example, the mask blank may not comprise any imaging structures like the mask itself but may comprise the layer material thereof.

In an example, the method can be used for repairing a defect of the lithography object.

In an example, the particle beam may comprise at least one of the following: an electron beam, an ion beam, a photon beam. For example, the same particle beam can be used for processing and/or examination purposes and for the purpose of setting the electrostatic charge state. For example, a particle beam created by the same particle beam source can be used for processing and/or examination purposes and for the purpose of setting the electrostatic charge state.

In an example, the provision of the particle beam for processing and/or examination purposes may comprise a provision of an electron beam from an electron beam source, wherein the provision of the particle beam for the purpose of setting the electrostatic charge state may likewise comprise a provision of an electron beam from this electron beam source.

In an example, the provision of the particle beam for processing and/or examination purposes may comprise a provision of an ion beam from an ion beam source, wherein the provision of the particle beam for the purpose of setting the electrostatic charge state may likewise comprise a provision of an ion beam from this ion beam source.

In an example, the provision of the particle beam for processing and/or examination purposes may comprise a provision of a photon beam (e.g. a laser beam) from a photon beam source (e.g. a laser beam source), wherein the provision of the particle beam for the purpose of setting the electrostatic charge state may likewise comprise a provision of a photon beam from this laser source.

It should also be mentioned that a further particle beam may also be provided within the scope of the provision of the particle beam for processing and/or examination purposes. For example, the processing and/or examination may comprise a two particle beam method. For example, one of these two particle beams can also be used to set the electrostatic charge state (as described herein).

In an example, the field of view on the sample may have an extent, preferably a rectangular extent, on the sample which does not go beyond a rectangle with dimensions of at most 10 μm×10 μm, preferably of at most 5 μm×5 μm, more preferably of at most 4 μm×4 μm, even more preferably of at most 3 μm×3 μm, and most preferably of at most 2 μm×2 μm. Thus, for example, the field on the sample accessible to the particle beam might not extend beyond these dimensions. For example, the field of view can be predefined from a technological point of view by the particle beam device that provides the particle beam.

A second aspect relates to a computer program comprising instructions for executing a method of the first aspect. A further aspect relates to a memory comprising this computer program.

A third aspect relates to a device for processing a sample with a particle beam. The device comprises: means for providing a particle beam in a field of view of the particle beam; wherein the means is configured to provide the particle beam for processing and/or examining the sample in the field of view, and wherein the means is configured to provide the particle beam for the purpose of setting an electrostatic charge state of the sample in the field of view.

The means for providing the particle beam can comprise, e.g a particle beam source. Further, the provision means may comprise one or more units for directing the particle beam at a location in the field of view of the particle beam. Further, the provision means may comprise one or more units for focusing the particle beam on a location in the field of view of the particle beam.

In an example, the device of the third aspect may further comprise:
a memory comprising instructions for executing a method of the first aspect;
a computer system which is capable of controlling the means for providing the particle beam, wherein, when the computer system executes the instructions from the memory, the device is caused to carry out a method of the first aspect.

For example, the computer system may comprise a computer, a computing unit, a microprocessor, etc. For example, the computer system may be communicatively coupled to the components of the device such that a signal output by the computer system can cause a change in a component of the device. For example, the means for providing the particle beam can thus be adapted to carry out the method of the first aspect.

In an example, the means for providing the particle beam can be configured such that a field of view of the particle beam on a sample has a rectangular shape, with the rectangular shape comprising dimensions of at most 10 μm×10 μm, preferably of 5 μm×5 μm, more preferably of at most 4 μm×4 μm, even more preferably of at most 3 μm×3 μm, and most preferably of at most 2 μm×2 μm.

It should be mentioned that the features (and also examples) of the method (or of the computer program) that are specified herein may also be applied or applicable correspondingly to the device mentioned. The features (and also examples) of the device that are specified herein may likewise be applied or applicable correspondingly to the method (and computer program) described herein.

### DESCRIPTION OF DRAWINGS

The following drawings are described in the detailed description below:

FIG. 1A-1C schematically shows the irradiation of an electrostatically uncharged lithographic mask with an electron beam, wherein the mask has a reference structure and a defect with four drift markers.

FIG. 2A-2C schematically shows the irradiation of the mask from FIGS. 1A-1C, wherein the mask has a positive electrostatic charge state.

FIG. 3A-3C schematically shows the irradiation of the mask from FIGS. 1A-1C, wherein the mask has a negative electrostatic charge state.

FIG. 4 schematically shows the method described herein, in which a particle beam is provided in a field of view for processing and/or examination purposes, wherein the particle beam is provided in the field of view for the purpose of setting an electrostatic charge state.

FIG. 5 shows a schematic flowchart in which a method as described herein is used.

FIG. 6 schematically elucidates a field of view of the particle beam as described herein in a side view, wherein the particle beam is provided for processing and/or examination purposes and also for the purpose of setting the electrostatic charge state on a sample.

FIG. 7 schematically elucidates a portion of a sample and a field of view of the particle beam as described herein in a plan view, wherein locations on the sample can be addressed by the particle beam via the field of view.

FIG. 8 schematically elucidates a first alternative example, in which the field of view of the particle beam for processing and/or examination purposes described herein differs from the field of view for setting the electrostatic charge state.

FIG. 9 schematically elucidates a second alternative example, in which the field of view of the particle beam for processing and/or examination purposes described herein differs from the field of view for setting the electrostatic charge state.

FIG. 10 schematically shows two options for setting the electrostatic charge state and the profile thereof during further processing and/or a further examination of the sample with the particle beam.

FIG. 11 schematically shows an example of means for providing a particle beam in a field of view of the particle beam.

### DETAILED DESCRIPTION

Examples of the method described herein and of the device described herein for processing and/or examining a sample are explained in detail below using the example of lithographic masks and a modified scanning electron microscope. However, the method need not be limited to the reflective and transmissive photomasks described below. Instead, the method described herein, within the scope of which the electrostatic charge state of a sample is set, can be used for any desired samples (e.g., for imprinting stamps for nanoimprint lithography, wafers, integrated circuits (ICs), micro-electromechanical systems (MEMS), nanoelectromechanical systems (NEMS), photonic integrated circuits (PICs), and biological samples). Further, the device described herein is not limited to the example described below. Instead of the modified scanning electron microscope discussed, it is also possible to employ any scanning particle microscope which uses for example a focused ion beam and/or a focused photon beam as energy source.

Currently preferred embodiments of the present invention are explained in more detail below with reference to the drawings.

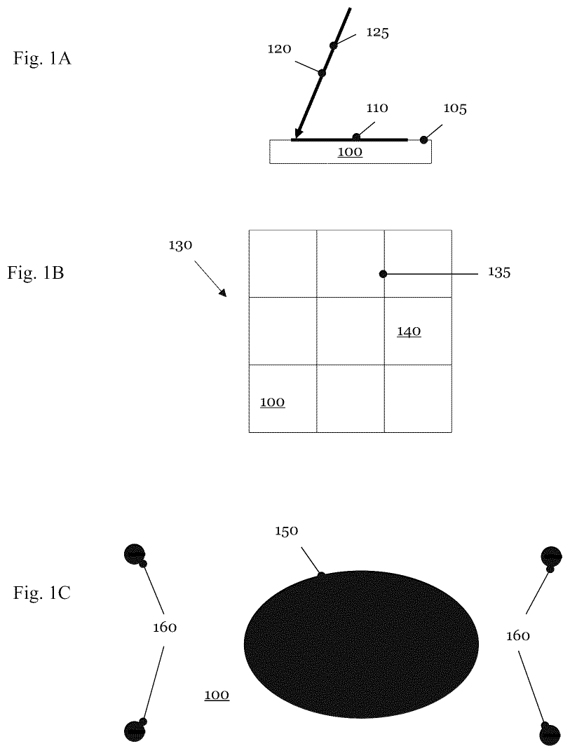

FIGS. 1A-1C show an exemplary lithographic mask 100 (hereinafter mask 100 for short) having a reference structure 130, a defect 150 and four reference elements 160, according to one example.

FIG. 1A shows a section through the mask 100, the surface 105 of which carries a pattern 110. The surface 105 of the mask 100 is irradiated by an electron beam 120.

For example, the electron beam can be provided at a specific position on the surface 105 for the purpose of processing the mask 100. For example, an electron beam-induced reaction may be caused on the mask 100 by the electron beam and a gas provided. The electron beam-induced reaction may comprise, e.g. an electron beam-induced deposition and/or electron beam-induced etching.

For example, the electron beam can also be provided at a specific position on the surface 105 for the purpose of examining the mask 100. For example, for imaging the mask 100, the electron beam can be raster-scanned over the surface. Electrons released thereby can be detected for image recording purposes. Thus, the electron beam can be used for imaging purposes, as known for a scanning electron microscope.

FIG. 1B presents a schematic view of a reference structure 130 of the mask 100. The exemplary reference structure 130 of FIG. 1B is a square that is divided into nine sub-squares 140 by lines 135. The reference structure 130 may be arranged in a manner distributed over the mask 100 at regular or irregular intervals. The reference structure 130 may be used to determine an electrostatic charge state of the mask 100 (or of a sample 100 in general terms) As a rule, both the positions of the reference structures 130 and the size thereof are known from the manufacturer of the mask 100. If this is not the case, the positions and the size of the reference structures 130 may be determined using for example a mask inspection tool.

FIG. 1C reproduces a schematic view of a defect 150 in the mask 100. The exemplary defect 150 is an excess-material defect or a dark defect 150. The method described herein may also be used for the precise processing and/or examination of a missing-material defect or a clear defect 150. The processing and/or examination of the defect may be implemented within the scope of a (e.g. multistage) repair process for the mask 100. Four reference elements 160 in the form of drift markers 160 are deposited around the defect 150 in FIG. 1C. The drift markers 160 may be deposited on the mask 100 around the defect 150 with the aid of an electron beam-induced deposition process while providing at least one precursor gas in the form of a deposition gas. The drift markers 160 span a two-dimensional (2-D) coordinate system in this example. Three reference elements 160 that are not arranged on a straight line are sufficient for spanning a 2-D coordinate system. The drift markers 160 are predominantly scanned periodically with the electron beam 120 during a repair process of the defect 150 in order to detect a drift of the defect 150 or of the drift markers 160 with respect to the reference positions of the drift markers 160. The change in the positions of the drift markers 160 with respect to their reference positions may also be used, in addition to determining a relative drift between the electron beam 120 and the drift markers 160 of the mask 100 or the defect 150, to ascertain an electrostatic charge state of the mask 100.

For the raster-scanning of the electron beam 120 over the defect 150 in the mask 100 during repair thereof, it may be advantageous to select the landing energy of the electrons 125 on the defect 150 to be as low as possible in order to make the diameter of the local chemical reaction induced by the electron beam 120 as small as possible. The provision of the particle beam for processing purposes described herein can be implemented, e.g. with electron landing energies of the order of 600 eV, preferably of the order of 400 eV and most preferably of the order of 300 eV or less. To image the drift markers 160, it may e.g. be advantageous to use electron landing energies that are also used to repair a defect. The provision of the particle beam for examination purposes described herein can be implemented, e.g. with electron landing energies of the order of 600 eV, preferably of the order of 400 eV and most preferably of the order of 300 eV or less. However, it may also be advantageous to implement the imaging of drift markers at different electron landing energies. The provision of the particle beam for examination purposes described herein can, e.g. be implemented with electron landing energies of the order of greater than 600 eV, for instance 3 keV.

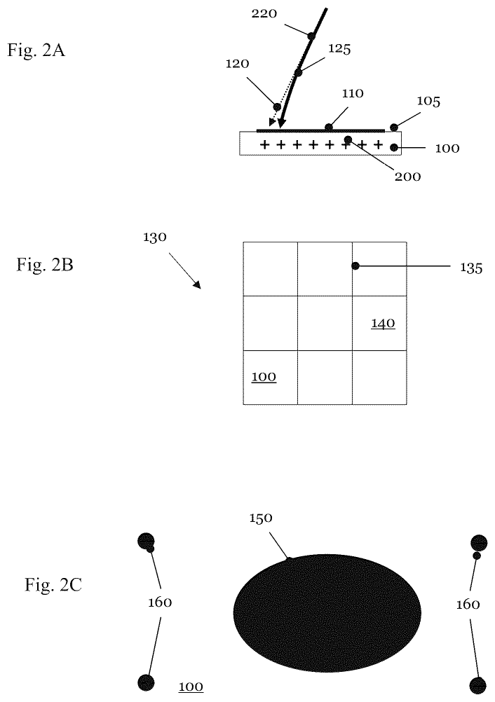

FIGS. 2A-2C once again repeat the illustrations of FIGS. 1A-1C. In contrast to FIGS. 1A-1C, the mask 100 in FIGS. 2A-2C however has a positive electrostatic charge state 200. The electric field of the positive electrostatic charge state 200 bends the electron beam 220 towards the surface 105 of the mask 100. For comparison, FIG. 2A additionally uses dashes to illustrate the electron beam 120 that would be incident on the surface 105 of the mask 100 if it were not electrostatically charged. FIG. 2B presents the reference structure 130 as is imaged by the electron beam 220 due to the positive electrostatic sample charge state 200 of the mask 100. In comparison to the reference structure 130 in FIG. 1B, the reference structure 130 of the positively electrostatically charged mask 100 appears smaller. FIG. 2C shows the imaging of the defect 150 and of the four drift markers 160, which the electron beam 220 acquires due to the positive electrostatic mask charge state 200 of these structural elements. The distance between the drift markers 160 in FIG. 2C appears smaller than in FIG. 1B.

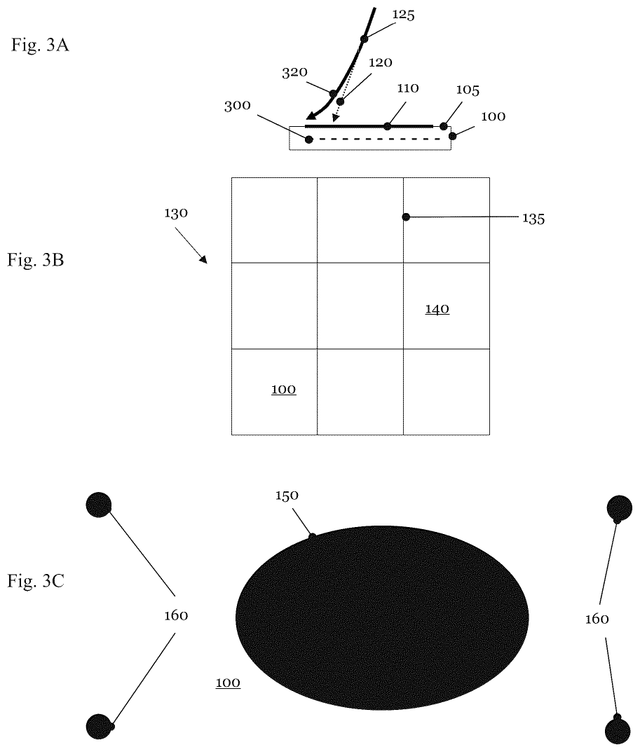

FIGS. 3A-3C show FIGS. 2A-2C, wherein the mask 100 now however has a negative electrostatic charge state 300 instead of a positive electrostatic charge state 200. The electric field of the negative sample charge state 300 bends the path of the electrons 125 of the electron beam 320 away from the surface 105 of the mask 100. For comparison, the trajectory of the electron beam 120 incident on a non-electrostatically charged mask 100 is once again illustrated in dashed form. As illustrated in FIG. 3B, the deflection of the electron beam 320 caused by the negative electrostatic charge state 300 increases the imaging of the reference structure 130 compared to the image thereof in FIG. 1B. The same applies to the imaging of the defect 150 and of the four drift markers 160 in FIG. 3C, again with reference to FIG. 1C.

It is possible to ascertain both the magnitude, i.e. numerical value, and the sign of the electrostatic charge state 200, 300 of the mask 100 from the change in size of the reference structure 130, caused by an electrostatic charge state 200, 300 of the mask 100 or, generally, of a sample 100. As elucidated by FIGS. 3A, 3B and 3C, an electrostatic sample charge state 200, 300 may also be ascertained from measured displacements of the drift markers 160 with respect to the reference positions thereof. This in turn applies to the absolute value and the sign of an electrostatic sample charge state 200, 300.

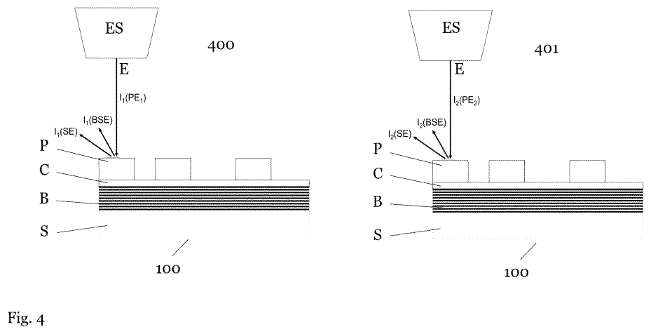

FIG. 4 schematically shows the method described herein, in which a particle beam is provided in a field of view for processing and/or examination purposes on a mask, wherein, in another step, the particle beam is provided in the field of view for the purpose of setting an electrostatic charge state.

A first situation 400 is depicted, in which the mask 100 is processed and/or examined (according to the method described herein). A second situation 401 can likewise be identified, in which the electrostatic charge state of the mask 100 is set (according to the method described herein).

In this example, the mask 100 comprises a mask for EUV lithography (an EUV mask). The EUV mask 100 may comprise a substrate S. A multilayer stack B may be applied to the substrate S. For example, the multilayer stack B may comprise a Bragg mirror. For example, the Bragg mirror may have a reflective effect with regard to the EUV radiation used during EUV lithography. A capping layer C may be applied to the multilayer stack B. For example, the capping layer C may serve to protect the multilayer stack. For example, one or more pattern elements P of the mask 100 may be applied to the capping layer C. For example, the pattern elements P might be absorber structures which absorb the EUV radiation during EUV lithography. For example, the pattern elements P might also have an absorbent and/or phase-shifting design in relation to the EUV radiation during EUV lithography. For example, the EUV mask may be electrically insulating. For example, one layer of the EUV mask may have electrically insulating properties. In such a case, a charge generated on the capping layer or in a pattern element P could not be discharged through the mask via the substrate to, e.g. a mask mount. Thus, once charged electrostatically, EUV masks cannot always be adapted in an optimal electrostatic fashion since, e.g. charge adaptation via a mask mount would not always be possible. However, the method described herein can allow the electrostatic charge state of EUV masks to be reliably set even during the processing and/or examination thereof.

As mentioned, a pattern element P can be defective since mask errors (e.g. in the case of EUV masks) cannot always be prevented. For example, the design of the mask 100 might indicate that a material of the pattern element P should be present at a given location, but this material might be missing. For example, the design of the mask 100 might indicate that no material should be present at given locations, but a pattern element P might have excess material there. These defects can also cause corresponding defects during lithography (e.g. during EUV lithography). Therefore, defective pattern elements P are usually repaired, e.g. by way of a particle beam-based process. However, as mentioned, the particle beam-based process may cause an (unwanted) electrostatic charge state of the mask.

Initially, reference is made by way of example to the first situation 400 in FIG. 4. This depicts an exemplary repair process for a pattern element P of the EUV mask 100. The repair process comprises processing and/or examining the EUV mask 100 using the electron beam E. The latter is made available by the electron beam source ES.

To use the electron beam E for processing and/or examination purposes, said electron beam can be provided with a certain set of electron beam parameters on the mask 100. By way of example, it is clear that the electron beam E is provided on the mask with an electron beam current of I1(PE1). The latter can also be referred to as primary beam current. For example, this electron beam E can be directed at a defective pattern element P. For example, this may serve to process the pattern element P. For example, electron beam-induced etching and/or deposition may be implemented in the process, within the scope of which a corresponding gas is provided at the defective pattern element P. However, the electron beam E can also be directed at the pattern element P for examination purposes, within the scope of which for example an image of the defective pattern element P is recorded.

For example, two types of electrons can be released from the material of the mask 100 as a result of the provision of the electron beam E on the mask for processing and/or examination purposes. On the one hand, backscattered electrons BSE can be released with a corresponding current I1(BSE) flowing from the mask. On the other hand, secondary electrons SE can be released with a corresponding current I1(SE) flowing from the mask. Thus, a negative charge can leave the sample via the current I1(BSE) and the current I1(SE). However, charge might also be introduced into the sample via the electron beam current I1(PE1) (e.g. electrons of I1(PE1) may remain in the mask). Depending on the interaction of the currents I1(PE1), I1(BSE), I1(SE), a corresponding net charge might accumulate in the mask (e.g. in the region of the incident electron beam). For example, the mask might charge positively or negatively as a result of the electron beam bombardment E. Further, the mask might also have an intrinsically present charge (without an electron beam bombardment).

However, this electrostatic charge state of the mask might deflect the electron beam E from its desired point of incidence (e.g. as explained for FIGS. 2 and 3).

This effect can be compensated for by way of setting the electrostatic charge state in the field of view of the electron beam as described herein.

In this respect, reference is made to the second situation 401 in FIG. 4. In the second situation 401, the electron beam E is provided in the field of view that was also accessible to the electron beam in the first situation 400. However, the electron beam E in the second situation is provided with a different set of electron beam parameters than in the first situation 400. By way of example, it is shown that the electron beam is now directed at the mask with an electron beam current of I2(PE2). Accordingly, a current of backscattered electrons of I2(BSE) and a current of secondary electrons of I2(SE) are released from the mask. These may be different from the currents present in the first situation 400. For example, the electron beam current I2(PE2) can be chosen such that a certain charge balance of these currents, and hence a specific electrostatic charge state of the mask, sets in. For example, the electron beam current I2(PE2) can be introduced in order to create a positive excess charge in the mask. For example, the electron beam current I2(PE2) can be introduced in order to create a negative excess charge in the mask. For example, the electron beam current I2(PE2) can be introduced such that the net charge of the mask is essentially zero (at least in the region of the point of incidence of the electron beam E on the mask). For example, the electron beam E can therefore be used in the second situation 401 for the purpose of compensating the electrostatic charge state of the mask 100.

As mentioned herein, the electrostatic charge state of the mask can be determined on the basis of the analysis of structures on the mask. This information can be used to set the electrostatic charge state and/or verify the set electrostatic charge state using the electron beam E. For example, it is possible to determine the electrostatic charge state level to be set, on the basis of the (currently present) determined charge state. For example, setting the charge state can be followed by a verification of the electrostatic charge state level induced in the mask during the setting process, on the basis of the previously determined charge state of the mask.

In an example, the electron beam E is directed at a location on the mask 100 in the second situation 401 at which the electron beam E was also directed in the first situation 400. Thus, the electrostatic charge state can be adapted, e.g. exactly in the region also processed and/or examined with the electron beam E. Thus, the electrostatic charge state can also be adapted locally at the location to be processed and/or examined.

For example, a repair shape may have been defined in the field of view of the electron beam during the processing and/or examination of the mask 100. The repair shape may comprise various pixels at which the electron beam E is provided, for example in order to cause an electron beam-induced reaction on the mask there for repair purposes. In an example, the electron beam E can likewise be provided on a pixel of the repair shape for the purpose of setting the electrostatic charge state. Hence, the electrostatic charge state can be introduced directly in the surroundings in which the repair also takes place.

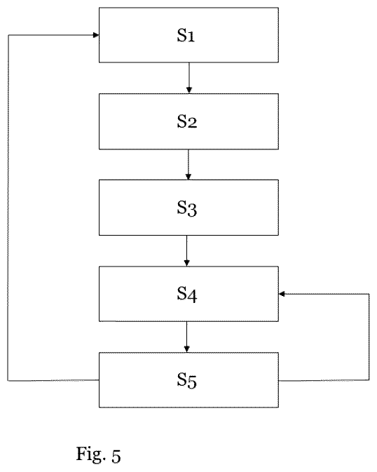

FIG. 5 shows a schematic flowchart in which a method as described herein is used. FIG. 5 elucidates that the steps of the method described herein may take place iteratively. The corresponding sequence is described in more detail below.

In a first step S1, the electron beam E can be used to perform a repair of a defect of the mask 100 (e.g. as shown in the first situation 400). To this end, the electron beam E can be provided on the mask for processing and/or examination purposes. As mentioned, a gas can be provided to this end, with the result that an electron beam-induced deposition and/or etching is rendered possible. In this context, the electron beam E can be provided at a first electron energy E1 and/or with a first electron beam current I1(PE1). For example, one or more repair steps may be implemented within the first step S1.

In a second step S2, the electrostatic charge state in the surroundings of the defect can be determined. For example, this can be implemented by determining the scale factor with the aid of drift markers on the mask 100. For example, this can be based on an electron beam image of the mask 100 using the electron beam E. For example, the electrostatic charge state can be determined spatially (e.g. at which positions on the mask which electrostatic charge state is present). For example, the electrostatic charge state can also be determined temporally (e.g. the (spatial) profile of the electrostatic charge state can be determined over a certain period of time). Determining the electrostatic charge state may, e.g. also comprise determining the (electric) polarization of the mask.

The second step S2 can, e.g. be implemented in parallel with the first step S1. For example, the repair in the first step S1 may include raster-scanning of the drift markers (e.g. for drift correction). For example, this information can also be used to determine the electrostatic charge state of the mask 100. For example, the second step S2 can also be implemented as a separate step in the sequence (in which no repair process is currently carried out).

The repair process can be interrupted in a third step S3. For example, this may comprise the gas no longer being provided for an electron beam-induced deposition and/or etching on the mask. For example, the third step S3 may comprise a certain waiting period following the interruption of the gas supply of the gas.

In a fourth step S4, the electron beam E can be provided for the purpose of setting the electrostatic charge state. Thus, the fourth step S4 may comprise the charge compensation of the mask 100. To this end, the electrostatically charged location of the mask can be irradiated with the electron beam E. Further, the surroundings of the electrostatically charged location of the mask can also be irradiated with the electron beam E. In this case, the electron beam E may comprise an electron energy E2 and/or an electron beam current of I2(PE) which are different from the electron energy E1 and I1(PE), respectively. In general, the electron energy, the electron current emanating from the electron beam source and further scanning parameters of the electron beam can be chosen in such a way in this step that the charge balance of the caused currents leads to discharge of the charges introduced during the repair procedure (in the first step). Thus, in the fourth step S4, the secondary particle balance can be set such that the charges introduced in the first step S1 are discharged or compensated.

The electrostatic charge state in the surroundings of the defect can be determined again in a fifth step S5. In this respect, reference can be made accordingly to the second step S2. For example, the fifth step S5 can be carried out in order to verify the electrostatic charge state set in the fourth step S4.

If it was possible to verify that the excess charges in the mask are no longer present (or only still present to the desired extent) as a result of setting the electrostatic charge state, then the repair procedure can be continued. To this end, e.g. the first step S1 of the sequence can be continued (as indicated in FIG. 5 by the corresponding arrow between the fifth step S5 and the first step S1).

However, if it was determined that setting the electrostatic charge state has not yielded the desired result, then the setting of the electrostatic charge state can be repeated. To this end, e.g. the fourth step S4 can be carried out in turn following the fifth step S5 (as indicated in FIG. 5 by the corresponding arrow from the fifth step S5 to the fourth step S4).

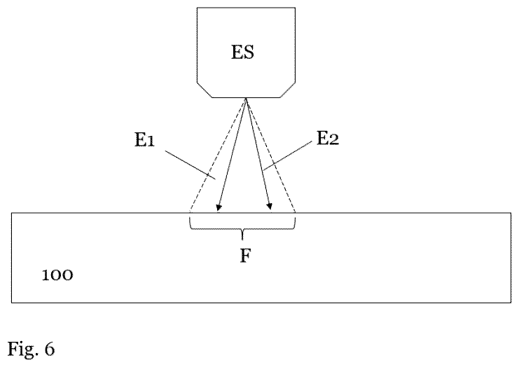

FIG. 6 schematically elucidates the field of view F of the particle beam described herein, within which the particle beam is provided for processing and/or examination purposes and for the purpose of setting the electrostatic charge state on a sample. An example of repairing a mask 100 is depicted schematically (as in FIG. 4). An electron beam source ES of an electron beam device is evident, wherein an electron beam can be provided on a mask 100 by way of the electron beam source. The region the electron beam is able to address on the mask 100 is restricted to the field of view F in this example (as described herein). In the depicted configuration, the electron beam E can only be directed at the mask 100 within this field of view F (e.g. without the sample and/or components of the electron beam device being moved). According to the method described herein, the electron beam can be provided on the mask 100 within this field of view F for the purpose of processing and/or examining the mask 100. To this end, an electron beam alignment E1 of the electron beam is depicted by way of example, the latter addressing a position within the field of view F for the purpose of processing and/or examining this location. According to the method described herein, the electron beam can likewise be provided on the mask 100 within the same field of view F for the purpose of setting the electrostatic charge state of the mask 100. To this end, an electron beam alignment E2 of the electron beam is depicted by way of example, the latter addressing a position within the field of view F for the purpose of setting the electrostatic charge state. Thus, within the scope of processing and/or examining, it is possible to also resort to this field of view F for the purpose of setting the electrostatic charge state (as described herein). In this regard, the same area on the mask 100 can be spanned by the same field of view F, when processing and/or examining and when setting the electrostatic charge state. Thus, within the scope of processing and/or an examination, the particle beam can be provided within the same boundaries (and also within the same area on the mask 100) for the purpose of setting the electrostatic charge state.

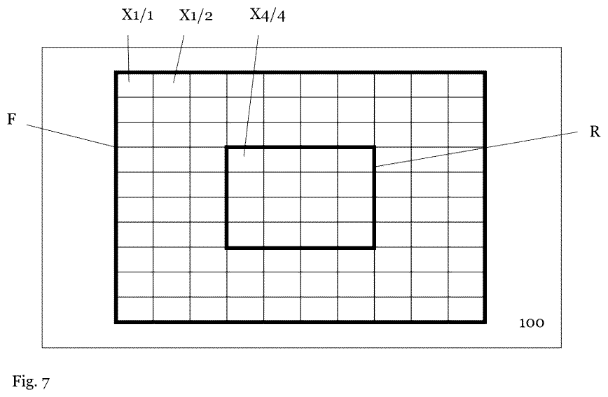

FIG. 7 schematically elucidates a portion of a sample 100 and an exemplary field of view F of the particle beam, wherein locations on the sample can be addressed by the particle beam via the field of view F. In an example, FIG. 7 may represent a repair of a mask 100 (as described for FIG. 6 and FIG. 4 as well). A portion of a mask 100 can be identified Different structures can be present within this portion. For example, one or more pattern elements and/or defects may be present in the portion of the mask 100. Also, the field of view F which may cover a subset of an area of the mask 100 can be identified. As described herein, an electron beam can be provided within this field of view F. However, the electron beam of the electron beam device (described herein) cannot be provided outside of this field of view F. Thus, the electron beam interaction can be restricted to the field of view F (for a configuration of the electron beam device) and consequently restricted to a portion of the mask 100. For example, the field of view F can be subdivided into pixels (as shown in FIG. 7). By way of example, a pixel X1/1, a pixel X1/2 and a pixel X4/4 are marked in FIG. 7. For example, the electron beam can be directed at each pixel within the field of view. Consequently, the electron beam can be directed at corresponding locations on the mask 100 which correspond to the pixels in the field of view F. However, the electron beam cannot be directed at locations outside of the field of view F.

As described herein, the electron beam can be provided on any desired pixel within this field of view F for the purpose of processing and/or examining the mask 100. Likewise, the electron beam can be directed at any pixel in the same field of view F for the purpose of setting the electrostatic charge state. Thus, the electron beam can be provided within the same area on the mask that is defined by the field of view F, when processing and/or examining and when setting the electrostatic charge state.

In an example, a predetermined active region R may be defined within the field of view F (as plotted in FIG. 7). For example, the predetermined active region can comprise a repair shape which delimits a defect repair of the mask 100 (as described herein). For example, processing and/or examining the mask 100 can be implemented within the predetermined active region R of the field of view F. To this end, the electron beam can be directed at one or more pixels which are located within the predetermined active region R (e.g. at pixel X4/4). For example, an electron beam can be directed at pixel X4/4 in order to cause an electron beam-induced deposition (or etching) there. Within the scope of processing/examination during the repair, different pixels within the predetermined active region can also be addressed multiple times by the electron beam.

In an example, the electron beam can be directed at pixels located within the predetermined active region R for the purpose of setting the electrostatic charge state (as described herein). For the purpose of setting the electrostatic charge state, the electron beam in an example can be directed at a pixel within the predetermined active region R which was also addressed by the electron beam for processing and/or examination purposes.

For the purpose of setting the electrostatic charge state, the electron beam in an example can also be directed at a pixel of the field of view F located outside of the predetermined active region (e.g. at pixel X1/1 and/or at pixel X1/2). For example, the processing and/or examination can be restricted to the pixels in the predetermined active region. However, it is possible to resort to all pixels in the field of view F for the purpose of setting the electrostatic charge state.

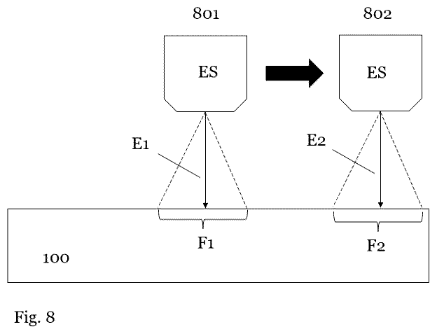

FIG. 8 schematically elucidates a first alternative example in which the field of view of the particle beam for processing and/or examination purposes, as described herein, differs from the field of view for the purpose of setting the electrostatic charge state. In this case, a mask 100 is processed and/or examined with an electron beam in a first position 801 of the electron beam source ES. A corresponding electron beam alignment E1 is depicted in a first field of view F1. The first field of view F1 can cover a first area on the mask 100. However, the electrostatic charge state can be set in a second position 802 of the electron beam source ES in that case. To this end, the electron beam source ES is locally offset. However, this is accompanied by a change in the field of view. Thus, the electrostatic charge state is set in a second field of view F2 in the second position 802. The second field of view may cover a second area of the mask 100 which differs from the first area. To set the electrostatic charge state, a corresponding second electron beam alignment E2 is shown in the second field of view F2 which differs from the first field of view F1.

However, for the method described herein, such a change in the field of view (e.g. from the field of view F1 to the field of view F2) need not (necessarily) be brought about by way of a change in the position of the electron beam source.

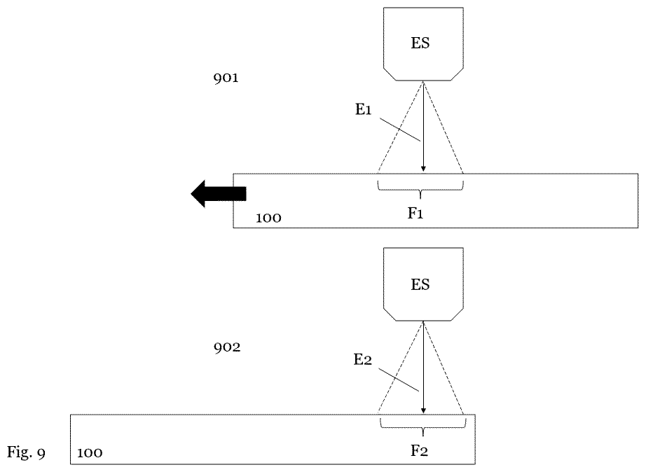

FIG. 9 schematically elucidates a second alternative example in which the field of view of the particle beam for processing and/or examination purposes, as described herein, differs from the field of view for the purpose of setting the electrostatic charge state. In this case, a mask 100 is processed and/or examined with an electron beam in a first position 901 of the mask 100. A corresponding electron beam alignment E1 in a first field of view F1 is depicted for the first position 901. The first field of view F1 can cover a first area on the mask 100. However, the electrostatic charge state can be set in a second position 902 of the mask 100 which is different from the first position 901. To this end, the mask 100 is locally offset. However, this is also accompanied by a change in the field of view. Thus, the setting in the second position 902 is implemented in a second field of view F2 which differs from the first field of view F1. Thus, the second field of view F2 may cover a second area of the mask 100 which differs from the first area of the mask 100.

However, for the method described herein, such a change in the field of view (e.g. from the field of view F1 to the field of view F2) need not (necessarily) be brought about by way of a change in the position of the mask 100.

In an example, the electrostatic charge state can be set by the electron beam in such a way that when the mask is processed by the electron beam, it is possible to ensure that a minimal repair size of the mask is below 12 nm. For example, excess material may protrude from a pattern element A. For example, in relation to an intended edge of the pattern element A, a certain length of excess material may protrude therefrom. For a repair, this excess material must be removed as far as the target edge, in order to repair the pattern element. The minimal repair size may, e.g. comprise the length of the excess material from the target edge, from where it is possible to ensure that the removal of this excess material during the repair leads to correction of the pattern element (or mask). As a result of the setting of the charge compensation described herein, it is e.g. possible to also remove very delicate protrusions, which e.g. protrude from the pattern element by between 5 nm and 12 nm, using the electron beam such that the mask is repaired.

In an example, the electrostatic charge state can be set by the electron beam in such a way that when the mask is processed by the electron beam, it is possible to ensure that a minimal repair size of the mask is below 15 nm, preferably below 12 nm or even below 11 nm. For example, this may be the case with silicon nitride-based masks. In an example, the electrostatic charge state can be set by the electron beam in such a way that when the mask is processed by the electron beam, it is possible to ensure that a minimal repair size of the mask is below 10 nm. For example, this may be the case with tantalum nitride-based masks.

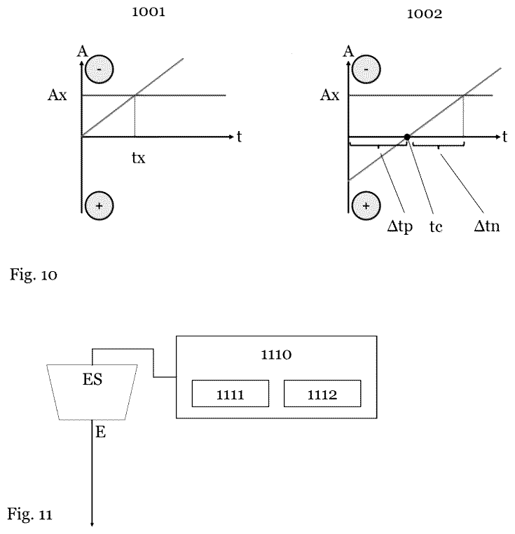

FIG. 10 schematically shows two options for setting the electrostatic charge state and the profile thereof during further processing and/or a further examination of the sample with the particle beam. Thus, it is conceivable, e.g. to keep a certain charge state in the surroundings of the defect for buffering purposes.

The left partial image 1001 shows the time profile of the electrostatic charge state at one location on a sample. The time t is plotted along the x-axis; the electrostatic charge state A (in arbitrary units) is plotted along the y-axis. The electrostatic charge state A can be, e.g. substantially zero at the start of processing and/or an examination with the particle beam (e.g. an electron beam). For elucidation purposes, FIG. 10 is explained by way of example using a mask repair with an electron beam (in relation to FIG. 4). For example, the mask 100 might not have a noteworthy electrostatic charge state at the start of the repair. For example, this may be due to intrinsic reasons, for example because no electron beam has been guided to the mask 100 yet. However, electrostatic charging of the mask 100 may have already been carried out for example (e.g. using the method described herein), and so the net charge of the mask 100 (or at a local location on the mask) is substantially zero.

For a time t>0 there is a provision of the electron beam E on the mask 100 for the purpose of processing and/or examining the latter. In the example of FIG. 10, electric charges are introduced into the mask as a result and charge the latter negatively at the location depicted. In the example illustrated, charges are generated in the mask 100 at a constant rate over time (q(t)=c), similarly to a capacitor charged with a current that is constant over time. Other temporal profiles of the electrostatic charge state are of course possible.

The horizontal line indicates a critical charge state Ax. In the case of electrostatic charge states that are less than the critical charge state Ax in terms of absolute value, electric fields are generated by the mask that disturb a charged particle beam (e.g. the electron beam E) only to a tolerable extent. On the other hand, above the line of the critical charge state Ax, the electric field caused by the electrostatic charge state deflects charged particles (e.g. electrons in the electron beam E) from their desired trajectory such that processing and/or examination is impaired to an extent that is no longer acceptable. In the left partial image 1001, a mask may be irradiated with the electron beam E without infringing the specification in the time interval starting from zero until the time tx.

The right partial image in FIG. 10 presents the temporal profile of the sample in the upper partial image (e.g. a mask), wherein the sample, at the start of the irradiation process, has a positive electrostatic charge that reaches the critical charge state Ax in terms of absolute value. For example, the positive sample charge state can be implemented by the process of setting the electrostatic charge state, as described herein, with the particle beam provided to this end. For example, for the positive sample charge state there can be an irradiation with electrons whose landing energy E₀ brings about a positive excess charge. For a time t>0 in partial image 1002 there is a provision of the electron beam E on the mask 100 for the purpose of processing and/or examining the latter (as for partial image 1001).

As a result of the positive pre-charge of the mask, the profile of the electrostatic charge state A is displaced by a time interval Δtp in partial image 1002. The time interval Δtp is between t=0 and t=tc, wherein the electrostatic charge is substantially zero at the time tc. Thus, the negative charges induced by the processing and/or examination initially cause a compensation of the previously introduced positive charges up to the time tc. However, after the time tc, the negative charges from processing and/or examination cause a negative electrostatic charge state (analogous to after time t=0 in partial image 1001). As a result of pre-existing charges, the time without violation of the specification by processing and/or an examination by way of irradiation with a particle beam can be doubled. For example, in the right partial image, the critical charge state Ax is reached after the time t=Δtp+Δtn. For example, the electrostatic charge state can be set anew thereafter.

In summary, the method described herein offers multiple advantages. For example, direct electrical contacting of the mask is not (necessarily) required. Further, the processing and/or examination of the mask is not substantially impaired by setting the electrostatic charge state in the field of view of the electron beam E. It is possible to jump systematically between processing and/or examination and the setting of the electrostatic charge state without making significant changes that influence the processing and/or examination. An advantage in one example is that it is possible to resort to the essential component used during the processing and/or examination-specifically the particle beam used to this end. Thus, this means for setting the electrostatic charge state can always be directly present. Thus, it is possible for example to make do without separate hardware in a particle beam device that serves to set the electrostatic charge state.

FIG. 11 shows an example of means for providing a particle beam in a field of view of the particle beam, in form of an electron beam source ES, wherein the means is configured to provide a particle beam (in the example of FIG. 11 an electron beam E) for processing the sample in the field of view, and wherein the means is configured to provide the particle beam for the purpose of setting an electrostatic charge state of the sample in the field of view FIG. 11 shows an exemplary embodiment comprising a control means 1110 coupled to the electron beam source ES and thus comprised in the means for providing a particle beam. The control means may be configured to control at least one parameter of the electron beam and/or may comprise hardware structure(s), e.g., like the shown computer system 1111 and memory 1112 which may, e.g., be couple to one another. The control means 1110 and/or its components 1111, 1112 may comprise software for controlling the electron beam source ES. The computer system may, e.g., be configured to control the means for providing the particle beam as described herein.

The electron beam source ES in the example of FIG. 11 further comprises means ES1 for controlling the beam path, e.g, configured to deflect the beam such that the beam may be directed onto a rectangular field of view FOV (shown in perspective), with the rectangular shape of the field of view FOV, e.g., comprising dimensions of at most 10 μm×10 μm. Said means ES1 may be coupled to and/or controlled by the control means 1110, e.g., by the computer system 1111 and/or according to a software protocol and/or data stored on the memory 1112.

The means ES1 may, e.g., comprise particle beam focusing optics configured to focus the particle beam and direct the particle beam on a sample and/or a particle beam steering device configured to steer the particle beam across a surface of the sample.

In some implementations, the means for providing a particle beam and/or the computer system 1111 can include a data processor and a storage device. The data processor in the means for providing a particle beam and/or the computer system 1111 can e.g., be configured to execute the functionalities described herein. The memory and/or the storage device can store data and/or software (components).

In detail, the memory may, e.g., store information (e.g., a table) about what electron beam current to use such that the net charge of the mask is zero, what electron beam current to use such that the net charge of the mask is positive, and/or what electron beam current to use such that the net charge of the mask is negative. Additionally or alternatively, the memory 1112 may, e.g., store information (e.g., a table or a function) that maps the amplitude of the electron beam current to the amount of net charge produced on the mask. For example, the methods described herein may be executed according to parameters stored in such tables in said memory 1112. E.g., the method may thus comprise looking up at least one value from said memory for initialization of the parameters of the method, e.g., comprising adjusting the electron beam current to perform the desired function(s). Said parameter(s) and/or requirement for the method according to which a suitable parameter may be retrieved from the memory 1112 may, e.g., comprise at least one of a landing energy of the particles in the particle beam incident on the sample, a wavelength of the particles in the particle beam incident on the sample, a flux density of the particles in the particle beam incident on the sample, an irradiation time of the particles in the particle beam incident on the sample, a particle beam current of the particles in the particle beam incident on the sample, an acceleration of the particles in the particle beam incident on the sample, or an acceleration voltage of the particles incident on the sample.

The hardware structures described herein and/or related to the method (e.g., the computing system 1111 may, e.g, access the memory 1112 in order to retrieve sad information stored therein and/or may control the particle beam source ES accordingly.

In some implementations, the means for providing a particle beam and/or the computer system 1111 can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The methods described in this document can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional features and properties respectively mentioned in this regard should also be understood to be disclosed in all combinations with one another. In particular, in the present case, the description of a feature comprised by an embodiment-unless explicitly explained to the contrary-should also not be understood such that the feature is essential or indispensable for the function of the embodiment.

Further examples of the invention are described below:
1. Method for processing a sample (100) with a particle beam (E), comprising:
   providing the particle beam (E) in a field of view (F) of the particle beam to process the sample; and
   providing the particle beam in the field of view (F) to set an electrostatic charge state of the sample.
2. Method according to Example 1, further comprising: providing a gas for removing and/or depositing a material in the field of view, at least in part on the basis of the particle beam provided in the field of view for the purpose of processing.
3. Method according to Example 1 or 2, wherein the particle beam is provided in a predetermined active region in the field of view for processing purposes.
4. Method according to Example 3, wherein the particle beam is provided in the predetermined active region in the field of view for the purpose of setting the electrostatic charge state of the sample.
5. Method according to any of Examples 1-4, wherein the particle beam is provided at the same location in the field of view for the purpose of processing and for the purpose of setting the electrostatic charge state.
6. Method according to any of Examples 1-5, wherein the particle beam is provided at different locations in the field of view for the purpose of processing and for the purpose of setting the electrostatic charge state.
7. Method according to any of Examples 1-6, wherein a location in the field of view at which the particle beam is provided for the purpose of processing and a location in the field of view at which the particle beam is provided for the purpose of setting the electrostatic charge state are spaced apart by at most 10 μm, preferably at most 5 μm, more preferably at most 4 μm, even more preferably at most 3 μm and most preferably at most 2 μm.
8. Method according to any of Examples 1-7, wherein at least one particle beam parameter differs between the provision of the particle beam in the field of view for the purpose of processing and the provision of the particle beam in the field of view for the purpose of setting the electrostatic charge state.
9. Method according to Example 8, wherein the at least one different particle beam parameter comprises at least one of the following parameters: a landing energy of the particles in the particle beam incident on the sample, a wavelength of the particles in the particle beam incident on the sample, a flux density of the particles in the particle beam incident on the sample, an irradiation time of the particles in the particle beam incident on the sample, a particle beam current of the particles in the particle beam incident on the sample, and an acceleration of the particles in the particle beam incident on the sample.
Method according to any of Examples 1-9, wherein the sample is not displaced between the provision of the particle beam in the field of view for the purpose of processing and the provision of the particle beam in the field of view for the purpose of setting the electrostatic charge state.
11. Method according to any of Examples 1-10, wherein the particle beam source (ES) of the particle beam is not displaced between the provision of the particle beam in the field of view for the purpose of processing and the provision of the particle beam in the field of view for the purpose of setting the electrostatic charge state.
12. Method according to any of Examples 1-11, wherein the particle beam is provided in the field of view for the purpose of setting the electrostatic charge state before the particle beam is provided in the field of view for the purpose of processing.
13. Method according to any of Examples 1-12, further comprising: determining an electrostatic charge state of the sample (100).
14. Method according to Example 13, wherein the electrostatic charge state is determined before the provision of the particle beam in the field of view for the purpose of setting the electrostatic charge state, with the provision of the particle beam in the field of view for the purpose of setting the electrostatic charge state being based at least in part on the determined electrostatic charge state.
15. Method according to either of Examples 13 and 14, wherein in order to verify the electrostatic charge state set by the particle beam provided, the electrostatic charge state is determined after the particle beam has been provided in the field of view for the purpose of setting the electrostatic charge state.
16. Method according to any of Examples 1-15, wherein there is an initial provision of the particle beam in the field of view for the purpose of processing and this is followed by the provision of the particle beam in the field of view for the purpose of setting the electrostatic charge state, with this being followed by a renewed provision of the particle beam in the field of view for the purpose of processing.
17. Method according to any of Examples 1-16, wherein the sample comprises a lithography object.
18. Method according to any of Examples 1-17, wherein the particle beam comprises at least one of the following: an electron beam, an ion beam, a photon beam.
19. Method according to any of Examples 1-18, wherein the field of view has an extent, preferably a rectangular extent, on the sample which does not go beyond a rectangle with dimensions of at most 10 μm×10 μm, preferably of at most 5 μm×5 μm, more preferably of at most 4 μm×4 μm, even more preferably of at most 3 μm×3 μm, and most preferably of at most 2 μm×2 μm.
20. Computer program comprising instructions for executing a method according to any of Examples 1-19.
21. Device for processing a sample (100) with a particle beam (E), comprising:
   means for providing a particle beam in a field of view (F) of the particle beam;
   wherein the means is configured to provide the particle beam for processing the sample in the field of view (F), and
   wherein the means is configured to provide the particle beam for the purpose of setting an electrostatic charge state of the sample in the field of view.
22. Device according to Example 21, further comprising:
   a memory comprising instructions for executing a method according to any of Examples 1-19;
   a computer system which is capable of controlling the means for providing the particle beam, wherein, when the computer system executes the instructions from the memory, the device is caused to carry out a method according to any of Examples 1-19.
23. Device according to either of Examples 21 and 22, wherein the means for providing the particle beam is configured such that a field of view (F) of the particle beam on a sample has a rectangular shape, with the rectangular shape comprising dimensions of at most 10 μm×10 μm, preferably of at most 5 μm×5 μm, more preferably of at most 4 μm×4 μm, even more preferably of at most 3 μm×3 μm, and most preferably of at most 2 μm×2 μm.
24. An apparatus comprising:
   a scanning particle microscope comprising:
      a particle source configured to generate a particle beam comprising a beam of particles;
      particle beam focusing optics configured to focus the particle beam and direct the particle beam on a sample;
      a particle beam steering device configured to steer the particle beam across a surface of the sample; and
      a particle detector configured to detect at least one of backscattered particles or secondary particles that result from interactions between the particle beam and the sample; and
   a control unit comprising electronic circuitry configured to control the scanning particle microscope to provide the particle beam to process the sample during a first time period and provide the particle beam to set an electrostatic charge state of the sample during a second time period,
   wherein the control unit is configured to set at least one parameter of the scanning particle microscope to a first respective value during the first time period, set the at least one parameter of the scanning particle microscope to a second respective value during the second time period, and the second respective value is different from the first respective value;
   wherein the control unit is configured to retrieve, from a storage device, information about a relationship between electrostatic charge states and the at least one parameter of the scanning particle microscope;
   wherein the control unit is configured to set the at least one parameter of the scanning particle microscope to the second respective value based on the information about the relationship between the charge states and the at least one parameter of the scanning particle microscope retrieved from the storage device.
25. The apparatus of Example 24, wherein the control unit comprises the storage device, and the storage device stores the information about the relationship between electrostatic charge states of the sample and the at least one parameter of the scanning particle microscope.
26. The apparatus of Example 24, wherein the storage device comprises a remote storage device located external to the apparatus, and the storage device stores the information about the relationship between electrostatic charge states of the sample and the at least one parameter of the scanning particle microscope.
27. The apparatus of any of Examples 24 to 26, wherein the at least one parameter of the scanning particle microscope comprises at least one of a landing energy of the particles in the particle beam incident on the sample, a wavelength of the particles in the particle beam incident on the sample, a flux density of the particles in the particle beam incident on the sample, an irradiation time of the particles in the particle beam incident on the sample, a particle beam current of the particles in the particle beam incident on the sample, an acceleration of the particles in the particle beam incident on the sample, or an acceleration voltage of the particles incident on the sample.
28. The apparatus of any of Examples 24 to 27, wherein the control unit is configured to set the electrostatic charge state during the second time period to reduce unwanted charge effects of the sample.
29. The apparatus of any of Examples 24 to 28, wherein the control unit is configured to perform a calibration procedure to determine a relationship between electrostatic charge states of the sample and the at least one parameter of the scanning particle microscope, and store information about the determined relationship between the electrostatic charge states of the sample and the at least one parameter of the scanning particle microscope in the storage device.
30. The apparatus of any of Examples 24 to 29, wherein the storage device stores a plurality of sets of information, each set of information includes information about a relationship between electrostatic charge states of a particular type of sample and at least one parameter of the scanning particle microscope;
   wherein the plurality of sets of information include information about respective relationships between electrostatic charge states of a plurality of types of samples and the at least one parameter of the scanning particle microscope;
   wherein the controller is configured to determine a type of the sample being processed, and retrieve from the storage device first information about the relationship between electrostatic charge states of the type of sample being processed and the at least one parameter of the scanning particle microscope;
   wherein the controller is configured to set the at least one parameter of the scanning particle microscope to the second respective value based on the first information about the relationship between the charge states of the type of sample and the at least one parameter of the scanning particle microscope retrieved from the storage device.
31. The apparatus of Example 30, wherein the plurality of types of samples comprise samples having coatings made of different materials;
   wherein each set of information includes information about a relationship between electrostatic charge states of a sample having a coating made of a particular material and the at least one parameter of the scanning particle microscope;
   wherein the plurality of sets of information include information about respective relationships between electrostatic charge states of a plurality of samples having coatings made of different materials and the at least one parameter of the scanning particle microscope;
32. The apparatus of any of Examples 24 to 30, wherein the storage device stores a plurality of sets of information, each set of information includes information about a relationship between electrostatic charge states of a sample having a particular identifier and at least one parameter of the scanning particle microscope;
   wherein the plurality of sets of information include information about respective relationships between electrostatic charge states of samples having a plurality of identifiers and at least one parameter of the scanning particle microscope;
   wherein the controller is configured to determine a first identifier of the sample being processed, and retrieve from the storage device first information about the relationship between electrostatic charge states of the sample having the first identifier and the at least one parameter of the scanning particle microscope;
   wherein the controller is configured to set the at least one parameter of the scanning particle microscope to the second respective value based on the first information about the relationship between the charge states of the sample having the first identifier and the at least one parameter of the scanning particle microscope retrieved from the storage device.
33. The apparatus of any of Examples 24 to 32, wherein the control unit is configured to set the at least one parameter of the scanning particle microscope to the second value during the second time period to set the electrostatic charge state that results in generation of a defined net charge on the sample.
34. The apparatus of any of Examples 24 to 33, further comprising a gas providing module, wherein the control unit is configured to control the gas providing module to provide a gas for removing and/or depositing a material on the sample, at least in part using the particle beam provided during the first time period;
   wherein the second respective value for the at least one parameter of the scanning particle microscope is selected such that setting the at least one parameter of the scanning particle microscope to the second respective value during the second time period results in more accurate removal and/or deposition of the material on the sample, as compared to setting the at least one parameter of the scanning particle microscope to the first respective value during the second time period.
35. The apparatus of any of Examples 24 to 34, wherein the control unit is configured to control the particle beam steering device and set the at least one parameter of the scanning particle microscope to the first respective value to provide the particle beam in a predetermined active region for the purpose of processing the sample during the first time period.
36. The apparatus of any of Examples 24 to 35 wherein the control unit is configured control the particle beam steering device and set the at least one parameter of the scanning particle microscope to the second respective value to provide the particle beam in the predetermined active region for the purpose of setting the electrostatic charge state of the sample during the second time period.
37. The apparatus of any of Examples 24 to 36, wherein the control unit is configured to control the particle beam steering device and set the at least one parameter of the scanning particle microscope to the first respective value to provide the particle beam in a first location for the purpose of processing the sample during the first time period,
   wherein the control unit is configured to control the particle beam steering device and set the at least one parameter of the scanning particle microscope to the second respective value to provide the particle beam in the first location for the purpose of setting the electrostatic charge state of the sample during the second time period.
38. The apparatus of any of Examples 24 to 37, wherein the scanning particle microscope comprises a scanning electron microscope, and the particle source comprises an electron beam source configured to generate an electron beam comprising a beam of electrons.
39. The apparatus of any of Examples 24 to 38, wherein the first time period does not overlap the second time period.
40. The apparatus of any of Examples 24 to 38, wherein the first time period overlaps the second time period.
41. The apparatus of any of Examples 24 to 40, wherein the control unit is part of the scanning particle microscope.
42. The apparatus of any of Examples 24 to 41, wherein the information about a relationship between electrostatic charge states and the at least one parameter of the scanning particle microscope comprises a first set of information regarding a first electrostatic charge state and a first set of at least one parameter value, and a second set of information regarding a second electrostatic charge state and a second set of at least one parameter value, and the second set of at least one parameter value is different from the first set of at least one parameter value.
43. The apparatus of Example 42, wherein the scanning particle microscope comprises a scanning electron microscope, and the particle beam comprises an electron beam;
   where the information about a relationship between electrostatic charge states and the at least one parameter of the scanning particle microscope comprises a first set of information regarding a first electrostatic charge state and a first electron beam current, and a second set of information regarding a second electrostatic charge state and a second electron beam current, wherein the second electrostatic charge state is different from the first electrostatic charge state, and the second electron beam current is different from the first electron beam current.
44. The apparatus of Example 43, wherein the information about a relationship between electrostatic charge states and the at least one parameter of the scanning particle microscope comprises a first set of information regarding a first electron beam current that can be used to generate a positive excess charge in the sample, a second set of information regarding a second electron beam current that can be used to generate a negative excess charge in the sample, and a third set of information regarding a third electron beam current that can be used to generate a net charge of essentially zero in the sample.
45. The apparatus of any of Examples 24 to 44, wherein the sample comprises at least one of a photolithography mask, a microchip, a wafer, an imprinting stamp for nanoimprint lithography, an integrated circuit, a micro-electromechanical system, a nanoelectromechanical system, a photonic integrated circuit, or a biological sample.
46. An apparatus comprising:
   a scanning particle microscope comprising:
      a first particle source configured to generate a first particle beam comprising a first beam of particles;
      a second particle source configured to generate a second particle beam comprising a second beam of particles;
      first particle beam focusing optics configured to focus the first particle beam and direct the first particle beam on a sample;
      second particle beam focusing optics configured to focus the second particle beam and direct the second particle beam on the sample;
      a first particle beam steering device configured to steer the first particle beam across a surface of the sample;
      a second particle beam steering device configured to steer the second particle beam across the surface of the sample; and
      a particle detector configured to detect at least one of backscattered particles or secondary particles that result from interactions between at least one of the first or second particle beam and the sample; and
   a control unit comprising electronic circuitry configured to control the scanning particle microscope to provide the first particle beam to process the sample and provide the second particle beam to set an electrostatic charge state of the sample.
47. The apparatus of Example 46, wherein the control unit is configured to set at least one parameter associated with the first particle beam to enable the first particle beam to be used to process the sample, and set at least one parameter associated with the second particle beam to enable the second particle beam to set an electrostatic charge state of the sample;
   wherein the control unit is configured to retrieve, from a storage device, information about a relationship between electrostatic charge states and at least one parameter associated with the second particle beam;
   wherein the control unit is configured to set the at least one parameter associated with the second particle beam based on the information about the relationship between the charge states and the at least one parameter of the second particle beam retrieved from the storage device.
48. A method comprising:
   scanning a particle beam on a sample to make a physical modification to the sample at a first location on the sample; and
   performing compensation raster scanning at the first location or a second location to set an electrostatic charge state of the sample, wherein the second location is spaced apart from the first location by at most 10 μm.
49. The method of Example 48, wherein the compensation raster scanning enables the physical modification to the sample to be performed more accurately at the first location, as compared to not performing the compensation raster scanning.
50. The method of Example 48 or 49, wherein the physical modification to the sample comprises at least one of depositing a material on the sample or removing a material from the sample.
51. The method of any of Examples 48 to 50, wherein performing the compensation raster scanning comprises setting the electrostatic charge state to reduce unwanted charge effects of the sample when processing the sample.

What is claimed is:

1. A method for processing a sample with a particle beam, comprising:
providing the particle beam in a field of view of the particle beam to process the sample; and
providing the particle beam in the field of view to set an electrostatic charge state of the sample.

2. The method of claim 1, wherein setting the electrostatic charge state results in a minimization of unwanted charge effects of the sample when processing the sample.

3. The method of claim 1, wherein setting the electrostatic charge state results in the generation of a defined net charge of the sample.

4. The method of claim 1, further comprising: providing a gas for removing and/or depositing a material in the field of view, at least in part on the basis of the particle beam provided in the field of view for the purpose of processing.

5. The method of claim 1, wherein the particle beam is provided in a predetermined active region in the field of view for the purpose of processing.

6. The method of claim 5, wherein the particle beam is provided in the predetermined active region in the field of view for the purpose of setting the electrostatic charge state of the sample.

7. The method of claim 1, wherein the particle beam is provided at the same location in the field of view for the purpose of processing and for the purpose of setting the electrostatic charge state.

8. The method of claim 1, wherein the particle beam is provided at different locations in the field of view for the purpose of processing and for the purpose of setting the electrostatic charge state.

9. The method of claim 1, wherein a location in the field of view at which the particle beam is provided for the purpose of processing and a location in the field of view at which the particle beam is provided for the purpose of setting the electrostatic charge state are spaced apart by at most 10 μm.

10. The method of claim 1, wherein at least one particle beam parameter differs between the provision of the particle beam in the field of view for the purpose of processing and the provision of the particle beam in the field of view for the purpose of setting the electrostatic charge state.

11. The method of claim 10, wherein the at least one different particle beam parameter comprises at least one of the following parameters: a landing energy of the particles in the particle beam incident on the sample, a wavelength of the particles in the particle beam incident on the sample, a flux density of the particles in the particle beam incident on the sample, an irradiation time of the particles in the particle beam incident on the sample, a particle beam current of the particles in the particle beam incident on the sample, or an acceleration of the particles in the particle beam incident on the sample.

12. The method of claim 1, wherein the sample is not displaced between the provision of the particle beam in the field of view for the purpose of processing and the provision of the particle beam in the field of view for the purpose of setting the electrostatic charge state.

13. The method of claim 1, wherein the particle beam source of the particle beam is not displaced between the provision of the particle beam in the field of view for the purpose of processing and the provision of the particle beam in the field of view for the purpose of setting the electrostatic charge state.

14. The method of claim 1, wherein the particle beam is provided in the field of view for the purpose of setting the electrostatic charge state before the particle beam is provided in the field of view for the purpose of processing.

15. The method of claim 1, further comprising: determining an electrostatic charge state of the sample.

16. The method of claim 15, wherein the electrostatic charge state is determined before the provision of the particle beam in the field of view for the purpose of setting the electrostatic charge state, with the provision of the particle beam in the field of view for the purpose of setting the electrostatic charge state being based at least in part on the determined electrostatic charge state.

17. The method of claim 15, wherein in order to verify the electrostatic charge state set by the particle beam provided, the electrostatic charge state is determined after the particle beam has been provided in the field of view for the purpose of setting the electrostatic charge state.

18. The method of claim 1, wherein there is an initial provision of the particle beam in the field of view for the purpose of processing and this is followed by the provision of the particle beam in the field of view for the purpose of setting the electrostatic charge state, with this being followed by a renewed provision of the particle beam in the field of view for the purpose of processing.

19. The method of claim 1, wherein the sample comprises a lithography object.

20. The method of claim 1, wherein the particle beam comprises at least one of the following: an electron beam, an ion beam, or a photon beam.

21. The method of claim 1, wherein the field of view has an extent on the sample which does not go beyond a rectangle with dimensions of at most 10 μm×10 μm.

22. A computer program comprising instructions for executing a method of claim 1.

23. A device for processing a sample with a particle beam, comprising:
means for providing a particle beam in a field of view of the particle beam;
wherein the means is configured to provide the particle beam for processing the sample in the field of view, and
wherein the means is configured to provide the particle beam for the purpose of setting an electrostatic charge state of the sample in the field of view.

24. The device of claim 23, further comprising:
a memory comprising instructions for executing a method of claim 1;
a computer system which is capable of controlling the means for providing the particle beam, wherein, when the computer system executes the instructions from the memory, the device is caused to carry out a method of claim 1.

25. The device of claim 23, wherein the means for providing the particle beam is configured such that a field of view of the particle beam on a sample has a rectangular shape, with the rectangular shape comprising dimensions of at most 10 μm×10 μm.
